(19) United States
(12) Patent Application Publication
(10) Pub. No.: US 2022/0259458 A1
(43) Pub. Date: Aug. 18, 2022

(54) POLISHING LIQUID COMPOSITION FOR SILICON OXIDE FILM

(71) Applicant: KAO CORPORATION, Tokyo (JP)

(72) Inventors: Masato SUGAHARA, Wakayama (JP); Norihito YAMAGUCHI, Wakayama (JP); Koki KUDO, Wakayama (JP)

(73) Assignee: KAO CORPORATION, Tokyo (JP)

(21) Appl. No.: 17/622,457

(22) PCT Filed: Jun. 19, 2020
(86) PCT No.: PCT/JP2020/024130

§ 371 Date: Dec. 23, 2021

(30) Foreign Application Priority Data
Jun. 26, 2019 (JP) 2019-118741

(51) Int. Cl. C09G 1/02

(52) U.S. Cl. CPC C09G 1/02; H01L 21/304

(57) ABSTRACT

Provided is a polishing liquid composition that is able to improve the polishing selectivity while maintaining the polishing rate of a silicon oxide film in one aspect.

An aspect of the present disclosure relates to a polishing liquid composition for a silicon oxide film. The polishing liquid composition contains cerium oxide particles (component A), a water-soluble polymer (component B), an anionic condensate (component C), and an aqueous medium. The component B is a polymer containing a constitutional unit b1 represented by the following formula (I).

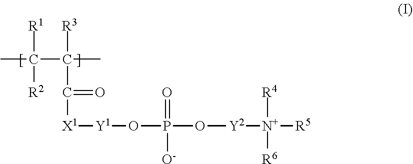

### TECHNICAL FIELD

The present disclosure relates to a polishing liquid composition that contains cerium oxide particles and is used for a silicon oxide film, a method for producing a semiconductor substrate by using the polishing liquid composition, and a method for polishing a substrate with the polishing liquid composition.

### BACKGROUND ART

Chemical mechanical polishing (CMP) is a planarization technique in which a working surface of a substrate to be polished is brought into contact with a polishing pad, and the substrate and the polishing pad are moved relative to each other while a polishing liquid is being supplied to the contact area between them, so that the uneven portion of the surface of the substrate undergoes a chemical reaction and is removed mechanically.

At present, the CMP technique is essential for, e.g., the planarization of an interlayer insulation film, the formation of a shallow trench element isolation structure (also referred to as an “element isolation structure” in the following), or the formation of a plug and embedded metal wiring in the manufacturing process of semiconductor devices. The recent rapid progress in multilayer semiconductor device with high definition has increased demand for high speed polishing as well as better flatness. For example, in the process of forming the Shallow trench element isolation structure, it is desirable that not only the polishing rate, but also the polishing selectivity of a polishing stopper film (e.g., a silicon nitride film) with respect to a film to be polished (e.g., a silicon oxide film) be improved. In other words, the polishing selectivity indicates that the polishing stopper film is less likely to be polished than the film to be polished.

JP 2010-153781 A (Patent Document 1) discloses a polishing method that uses a polishing agent and a polishing pad. The polishing agent contains abrasive gains of at least one component of tetravalent cerium oxide particles and tetravalent cerium hydroxide particles. The primary particle size of the abrasive grains is 1 nm or more and 40 nm or less. The Shore D hardness of the polishing pad is 70 or more.

JP 2017-178986 A (Patent Document 2) proposes a polishing liquid that contains abrasive grains including cerium oxide particles, a polymer compound having at least one selected from a carboxylic acid group and a carboxylic acid base, a particular polyether amine compound, and water.

JP 2015-516476 A (Patent Document 3) proposes a chemical mechanical polishing composition that contains a ceria polishing agent a nonionic polymer such as polyalkylene a nitrogen-containing zwitterionic compound, a phosphoric acid, a sulfonic acid copolymer, an anionic copolymer, a polymer containing a quaternary amine, a pH adjusting compound, and water.

### DISCLOSURE OF INVENTION

An aspect of the present disclosure relates to a polishing liquid composition for a silicon oxide film. The polishing liquid composition contains cerium oxide particles (component A), a water-soluble polymer (component B), an anionic condensate (component C), and an aqueous medium. The component B is a polymer containing a constitutional unit b1 represented by the following formula (I).

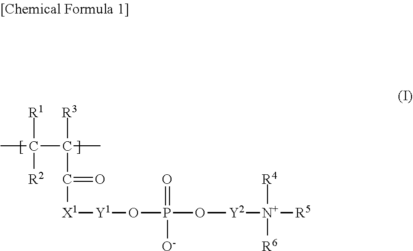

In the formula (I), R¹, R², R³, R⁴, R⁵, and R⁶ are the same or different and represent a hydrogen atom, a methyl group, or an ethyl group, X¹ represents O or NH, and Y¹ and Y² are the same or different and represent an alkylene group having 1 to 4 carbon atoms.

Another aspect of the present disclosure relates to a method for producing a semiconductor substrate. The method includes polishing a film to be polished with the polishing liquid composition of the present disclosure.

Another aspect of the present disclosure relates to a polishing method that includes polishing a film to be polished with the polishing liquid composition of the present disclosure.

### DESCRIPTION OF THE INVENTION

In the field of semiconductor, wiring has been required to be finer and more complicated due to a high level of integration in recent years. This in turn requires that the polishing selectivity is improved while the polishing rate is maintained in the CMP process.

The present disclosure provides a polishing liquid composition for a silicon oxide film that is able to improve the polishing selectivity while maintaining the polishing rate of a silicon oxide film, a method for producing a semiconductor substrate by using the polishing liquid composition, and a polishing method with the polishing liquid composition.

The present inventors conducted intensive studies and made the findings that the use of a polishing liquid composition containing cerium oxide (also referred to as “ceria” in the Mowing) particles that serve as abrasive grains, a particular water-soluble polymer, and a particular anionic condensate could improve the polishing selectivity and also maintain the polishing rate of a silicon oxide film.

In one or more embodiments, the present disclosure relates to a polishing liquid composition for a silicon oxide film (also referred to as a “polishing liquid composition of the present disclosure” in the Mowing). The polishing liquid composition contains cerium oxide particles (component), a water-soluble polymer (component B), an anionic condensate (component C), and an aqueous medium. The component B is a polymer containing a constitutional unit b1 represented by the formula (I).

In one aspect the present disclosure can provide a polishing liquid composition for a silicon oxide film that is able to improve the polishing selectivity while maintaining the polishing rate of a silicon oxide film.

The details of the mechanism of the effects of the present disclosure are not hilly clear, but can be considered as follows.

In order to improve the polishing rate, it is necessary to increase the frequency with which the ceria particles come into contact with the object to be polished (i.e., the silicon oxide film). The component B acts as a binder because it is adsorbed on both the ceria particles and the silicon oxide film. This may increase the contact frequency of the ceria particles and thus improve the polishing rate. On the other hand, a protective film needs to be formed on a polishing stopper film to reduce the polishing rate of the polishing stopper film. The component C has a rigid structure and allows a protective film to be efficiently firmed on the polishing stopper film. That is, the component B has the effect of improving the polishing rate of the object to be polished (i.e., the silicon oxide film) and the component C has the effect of reducing the polishing rate of the polishing stopper film. Since these effects are exerted individually, it may be possible to improve the polishing selectivity and also to maintain the polishing rate of the silicon oxide film.

However, the present disclosure should not be interpreted solely by the above mechanism.

In the present disclosure, the “polishing selectivity” means the same as the ratio of the polishing rate of the film to be polished (e.g., the silicon oxide film) to the polishing rate of the polishing stopper film (e.g., a silicon nitride film or a polysilicon film) (polishing rate of film to be polished/polishing rate of polishing stopper film). The higher the “polishing selectivity,” the larger the ratio of polishing rate.

[Cerium Oxide (Ceria) Particles (Component A)]

The polishing liquid composition of the present disclosure contains ceria particles (also referred to simply as a “component A” in the following) as polishing abrasive grains. The component A may be either positively charged ceria or negatively charged ceria. The chargeability of the component A can be confirmed by measuring a potential (surface potential) on the surface of the abrasive grains with, e.g., an electroacoustic method, or an electrokinetic sonic amplitude (ESA) method. The surface potential can be measured with, e.g., “ZetaProbe” (manufactured by Kyowa Interface Science Co., Ltd.) and specifically by a method as described in Examples. The component A may be of one type or two or more different types.

The production method, shape, and surface state of the component A are not limited. Examples of the component A include colloidal ceria irregularly-shaped ceria and ceria-coated

The colloidal ceria can be obtained by a build-up puss, e.g., in the method described in Examples 1 to 4 of JP 2010-505735 A.

The irregularly-shaped aria may be, e.g., crashed ceria. An embodiment of the crushed ceria may be, e.g., calcined and crushed ceria obtained by calcining and crushing a cerium compound such as cerium carbonate or cerium nitrate. Another embodiment of the crashed ceria may be, e.g., single crystal crashed ceria obtained by wet-crashing ceria particles in the presence of an inorganic acid or organic acid. The inorganic acid used in the wet-crushing process may be, e.g., a nitric acid. The organic acid used in the wet-crushing process may be, e.g., an organic acid having a carboxyl group. Specifically, the organic acid may be at least one selected from picolinic acid, glutamic acid, aspartic acid, aminobenzoic acid, and p-hydroxybenzoic acid. The wet-crushing process may be, e.g., wet-crushing with a planetary bead mill or the like.

The ceria-coated silica may be, e.g., composite particles obtained by covering at least a part of the surface of individual silica particles with granular cerin, e.g., with the method described in Examples 1 to 14 of JP 2015-63451 A or Examples 1 to 4 of JP 2013-119131 A. The composite particles tan be obtained by e.g., deposition of ceria on the silica particles.

The component A may have, e.g., a substantially spherical shape, a polyhedral shape, or a raspberry-like shape.

The average primary particle size of the component A is preferably 5 nm or more, more preferably 10 nm or more, and Either preferably 20 nm or more from the viewpoint of improving the polishing rate. Furthermore; the average primary particle size of the component A is preferably 300 nm or less, more preferably 200 nm or less and further preferably 150 nm or less from the viewpoint of reducing the occurrence of polishing scratches. More specifically, the average primary particle size of the component A is preferably 5 nm or more and 300 nm or less, more preferably 10 nm or more and 200 nm or less, and further preferably 20 am or more and 150 nm or less. In the present disclosure, the average primary particle size of the component A is calculated by using a BET specific surface area S (m²/g) that is determined with a BET (nitrogen adsorption) method. The BET specific surface area can be measured by a method as described in Examples.

The content of the component A in the polishing liquid composition of the present disclosure is preferably 0.001% by mass or more, more preferably 0.05% by mass or more, even more preferably 0.07% by mass or more, and further preferably 0.1% by mass or more with respect to 100% by mass of the total content of the component A, the component B, and water from the viewpoint of improving the polishing rate. Furthermore, the content of the component A is preferably 10% by mass or less more preferably 5% by mass or less, even more preferably 2.5% by mass or less, and Norther preferably 1% by mass or less with respect to 100% by mass of the total content of the component A, the component B, and water from the viewpoint of reducing the occurrence of polishing scratches. More specifically the content of the component A is preferably 0.001% by mass or more and 10% by mass or less, more preferably 0.05% by mass or more and 5% by mass or less, even more preferably 0.07% by mass or more and 2.5% by mass or less, and further preferably 0.1% by mass or more and 1% by mass or less with respect to 100% by mass of the total content of the component A, the component B, and water. When the component A includes a combination of two or more types of ceria particles, the content of the component A is the total content of the two or more types of ceria particles.

[Water-Soluble Polymer (Component B)]

The polishing liquid composition of the present disclosure contains a water-soluble polymer (also referred to simply as a “component B” in the following), In one or more embodiments, the component B is a polymer containing a constitutional unit b1, as will be described later. The component B may be of one type or two or more different types. In the present disclosure, the term “water-soluble” means that the solubility of the polymer is 0.5 g/100 mL or more, and preferably 2 g/100 mL or more in water (at 20° C.).

An embodiment of the component B may include a homopolymer composed of a constitutional unit b1, as will be described later, or a copolymer containing the constitutional unit b1. Other embodiments of the component B may include at least one copolymer selected from the following: a copolymer containing the constitutional unit b1 and a constitutional unit b2, as will be described later: a copolymer containing the constitutional unit b1 and a constitutional unit b3, as will be described later; and a copolymer containing the constitutional unit b1, the constitutional unit b2, and the constitutional unit b3. The component B may be of one type or two or more different types.

(Constitutional Unit b1)

The constitutional unit b1 is represented by the following formula (I). The constitutional unit b1 may be of one type or two or more different types.

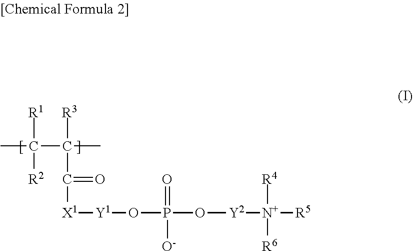

In the formula (I), R¹, R², R³, R⁴, R⁵, and R⁶ are the same or different and represent a hydrogen atom, a methyl group, or an ethyl group, X¹ represents O or NH, and Y₁ and Y² are the same or different and represent and alkylene group having 1 to 4 carbon atoms.

In the formula (I), R¹ and R² each are preferably a hydrogen atom from the viewpoint of availability of unsaturated monomers, polymerizability of monomers, and improving the polishing rate. R³ is preferably a hydrogen atom or a methyl group, and more preferably a methyl group from the viewpoint of availability of unsaturated monomers, polymer ability of monomers, and improving the polishing rate. R⁴, R⁵, and R⁶ are preferably a methyl group from the viewpoint of availability of unsaturated monomers, polymerizability of monomer and improving the polishing rate. X¹ is preferably O (oxygen atoms) firm the viewpoint of availability of unsaturated monomers, polymerizability of monomers; and improving the polishing rate and Y² each are preferably an alkylene group having 2 or 3 carbon atoms and more preferably an alkylene group having 2 carbon atoms from the viewpoint of availability of unsaturated monomers, polymerizability of monomers, and improving the polishing rate.

The constitutional unit b1 may be a constitutional unit derived from a monomer containing a methacryloyloxyethyl phosphobetaine structure from the viewpoint of availability of unsaturated monomers, polymerizability of monomers and improving the polishing rate. Specifically the constitutional unit b1 may be a constitutional unit derived from a monomer such as 2-methacryloyloxyethyl phosphorylcholine (MPC).

In the present disclosure, a betaine structure is defined to have a positive charge and a negative charge in the same molecule so that the charges are neutralized. In the betaine structure, the positive charge and the negative charge are preferably located in positions that are not adjacent to each other and also preferably located in positions that are separated by at least one atom. A phosphobetaine structure is a structure in which the negative charge of the betaine structure occurs as a result of dissociation of a phosphate group.

(Constitutional Unit b2)

The constitutional unit b2 is at least one constitutional unit selected from a constitutional unit represented by the following formula (II), a constitutional ma represented by the following formula and a constitutional unit represented by the following formula (IV). The constitutional unit b2 may be of one type or two or more different types.

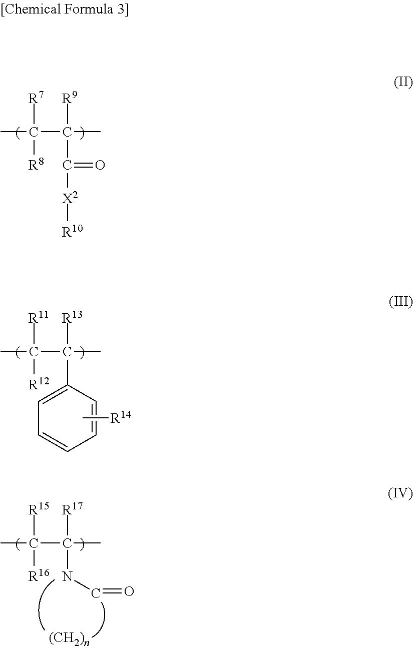

In the formula, (II), R⁷, R⁸, and R⁹ are the same or different and represent a hydrogen atom, a methyl group, or an ethyl group, X² represents O or NH, and R¹⁰ represents a hydrocarbon group.

In the formula (II), R⁷ and R⁸ are preferably a hydrogen atom from the viewpoint of availability of unsaturated monomers, polymerizability of monomers, and improving the polishing rate, R⁹ is preferably a hydrogen atom or a methyl group, and more preferably a methyl group from the viewpoint of availability of unsaturated monomers, polymerizability of monomers, and improving the polishing rate. X² is preferably O (oxygen atom) from the viewpoint of availability of unsaturated monomers, polymerizability of monomers, and improving the polishing rate. The hydrocarbon group of R¹⁰ may be in any of a linear, branched, or cyclic form. The hydrocarbon group of R¹⁰ is preferably an alkyl group having 1 to 22 carbon atoms, an aryl group having 6 to 22 carbon atoms or an aralkyl group having 7 to 22 carbon atoms, and more preferably an alkyl group having 1 to 22 carbon atoms or an aralkyl group having 7 to 22 carbon atoms from the viewpoint of availability of unsaturated monomers, polymerizability of monomers, and improving the polishing rate. Specific examples of R¹⁰ include an alkyl group such as a butyl group and an aralkyl group such as a benzyl group.

In the formula (III), R¹¹, R¹², and R¹³ are the same or different and represent a hydrogen atom, a methyl group, or an ethyl group and R¹⁴ represents a hydrogen atom, a hydroxyl group, a hydrocarbon group, or an alkoxy group.

In the formula (III), R¹¹ and R¹² are preferably a hydrogen atom from the viewpoint of availability of unsaturated monomers, polymerizability of monomers and improving the polishing rate. R¹³ is preferably a hydrogen atom or a methyl group from the viewpoint of availability of unsaturated monomers, polymerizability of monomers, and improving the polishing rate. The hydrocarbon group of R¹⁴ may be in either linear or branched form. The hydrocarbon group of R¹⁴ may be an alkyl group having 1 to 4 carbon atoms or an aryl group having 6 to 10 carbon atoms from the viewpoint of availability of unsaturated monomers, polymerizability of monomers, and improving the polishing rate. The alkoxy group of R¹⁴ may be an alkoxy group having 1 to 4 carbon atoms from the viewpoint of improving the polishing rate. R¹⁴ is preferably a hydrogen atom from the viewpoint of availability of unsaturated monomers, polymerizability of monomers and improving the polishing rate.

In the formula (IV), R¹⁵, R¹⁶, and R¹⁷ are the same or different and represent a hydrogen atom, a methyl group, or an ethyl group and n represents an integer of 2 to 12.

In the formula (IV), R¹⁵, R¹⁶, and R¹⁷ are preferably a hydrogen atom from the viewpoint of improving the polishing rate. Moreover, n is preferably an integer of 2 to 12, more preferably an integer of 3 to 10, and further preferably an integer of 4 to 6 from the viewpoint of improving the polishing rate.

In one or more embodiments, the constitutional unit represented by the formula may be a constitutional unit derived from at least one monomer selected from butyl methacrylate (BMA), 2-ethylhexyl methacrylate (EHMA), lauryl methacrylate (LMA) stearyl methacrylate (SMA), and benzyl methacrylate (BzMA).

In one or more embodiments the constitutional unit represented by the formula may be a constitutional unit derived from styrene (St) or α-methyl styrene (αMSt).

In one or more embodiments, the constitutional unit represented by the formula (IV) may be a constitutional unit derived nom vinylpyrrolidone (VP).

When the component B is a copolymer containing the constitutional unit b1 and the constitutional unit b2, in one or more embodiments, the component B may be at least one selected from a 2-methacryloyloxyethyl phosphorylcholine/butyl methacrylate copolymer (MPC/BMA), a 2-methacryloyloxyethyl, phosphorylcholine/stearyl methacrylate copolymer (MPC/SMA), a 2-methacryloyloxyethyl phosphorylcholine/benzyl methacrylate copolymer (MPC/BzMA), a 2-methacryloyloxyethyl phosphorylcholine/α-methyl styrene copolymer MPC/VP), and a 2-methacryloyloxyethyl phosphorylcholine/vinylpyrrolidone copolymer MPC/VP) from the viewpoint of improving the polishing rate.

When the component 13 is a copolymer containing the constitutional unit b1 and the constitutional unit b2, the total content of the constitutional unit b1 and the constitutional unit b2 in all the constitutional units of the component B is preferably 90 to 100 mol %, more preferably 95 to 100 mol %, and further preferably 99 to 100 mol % from the viewpoint of improving the polishing rate.

When the component Bis a copolymer containing the constitutional unit b1 and the constitutional unit b2, the molar ratio of the constitutional unit b1 to the constitutional unit b2 (b1/b2) in all the constitutional units of the component 13 is preferably 1.0/90 or more, more preferably 20/80 or more, even more preferably 30/70 or more, still more preferably 40/60 or more, yet more preferably 50/50 or more, further preferably 60/40 or more, and even further preferably 70/30 or more from the viewpoint of improving the polishing rate. From the same viewpoint, the molar ratio is preferably 98/2 or less, and more preferably 95/5 or less.

(Constitutional Unit b3)

In one or more embodiments, the constitutional unit b3 is preferably a constitutional unit having at least one group selected from a primary amino group, a secondary amino group, a tertiary amino pulp, a quaternary ammonium group, and salts of these groups from the viewpoint of improving the polishing rate and the flatness. Examples of the salts include a chloride (Cl⁻) salt, a bromide (Br) salt, and a sulfuric add (SO₄²) salt. The constitutional unit b3 may be of one type or two or more different types.

Monomers forming the constitutional unit b3 are preferably at least one selected from methacryloyloxyethyl dimethylethylaminium (MOEDES), 2-hydroxy-3-(trimethylaminio)propyl methacrylate (THMPA), methacryloylethyl trimethylaminium (MOETMA), 2-aminoethyl methacrylate (MOEA)- and 2-(diethylamino)ethyl methacrylate (MOEDEA), more preferably at least one selected from THMPA, MOEA, and MOEDEA, and further preferably THMPA from the viewpoint of improving the polishing rate and the flatness.

When the component B is a copolymer containing the constitutional unit b1 and the constitutional unit b3, in one or more embodiments, the component B may be a 2-methacryloyloxyethyl phosphorylcholine/2-hydroxy-3-(trimethylaminio)propyl methacrylate copolymer (MPC/THMPA) from the viewpoint of improving the polishing rate and the flatness.

The component B may further contain additional constitutional units other than the constitutional units b1, b2, and b3. The additional constitutional units may include, e.g., hydroxyethyl methacrylate and acrylonitrile.

From the viewpoint of improving the polishing rate, the weight average molecular weight of the component B is preferably 1,000 or more, more preferably 5,000 or more, and further preferably 10,000 or more. Furthermore, the weight average molecular weight of the component B is preferably 300,000,000 or less, more preferably 2,000,000 or less, and further preferably 1,000,000 or less. More specifically the weight average molecular weight of the component B is preferably 1,000 or more and 3,000,000 or less, more preferably 5,000 or more and 2,000,000 or less, and further preferably 10,000 or more and 1,000000 or less. The weight average molecular weight of component B can be measured by e.g., gel permeation chromatography (GPC).

The content of the component B in the polishing liquid composition of the present disclosure is preferably 0.001% by mass or more, more preferably 0.0025% by mass or more, and father preferably 0.005% by mass or more with respect to 100% by mass of the total content of the component A, the component B, and the aqueous medium from the viewpoint of improving the polishing rate. From the same viewpoint, the content of the component B is preferably 1% by mass or less, more preferably 0:2% by mass or less, and further preferably 0.1% by mass or less with respect to 100% by ma of the total content of the component A the component B, and the aqueous medium. More specifically, the content of the component B is preferably 0.001% by mass or more and 1% by mass or less, more preferably 0.0025% by mass or more and 0.2% by mass or less, and further preferably 0.005% by mass or more and 0.1% by mass or less with respect to 100% by mass of the total content of the component A, the component B, and the aqueous medium. When the component B includes a combination of two or more types of polymers, the content of the component B is the total content of the two or more types of polymers.

From the viewpoint of improving the polishing rate, the mass ratio NB of the component A to the component B (content of component A/content of component B) in the polishing liquid composition of the present disclosure is preferably 1 or morn, more preferably 2.5 or more, and further preferably 5 or more. Furthermore, the mass ratio A/B is preferably 500 or less, more preferably 100 or less, and further preferably 50 or less. More specifically, the mass ratio NB is preferably 1 or more and 500 or less, more preferably 2.5 or more and 100 or less, and further preferably 5 or more and 50 or less.

[Anionic Condensate (Component C)]

In one or more embodiments, the polishing liquid composition of the present disclosure contains an anionic condensate (also referred to simply as a “component C” in the following). The component C may be of one type or two or more different types. In one or more embodiments the presence of the component C in the polishing liquid composition of the present disclosure can reduce the polishing rate of the silicon nitride film and improve the polishing selectivity, Further, in one or more embodiments the component C can serve to reduce the polishing rate of the silicon nitride film when it is overpolished, and also to reduce a dishing rate during overpolishing. The “dishing” means a dish-like depression mused by excessive polishing of a film disposed in a recess. The component C is preferably water soluble and has a solubility of preferably 0.5 g/100 mL or more in water (at 20° C.).

In one or more embodiments, the component C is preferably an anionic condensate having an aromatic ring in the main chain, and more preferably contains a constitutional unit derived than an aromatic monomer having an anionic group (also referred to as an “anionic constitutional unit” in the Mowing) from the viewpoint of maintaining the polishing rate, improving the polishing selectivity, and reducing the polishing rate of the silicon nitride film and the dishing rate during overpolishing and particularly from the viewpoint of reducing the polishing rate of the silicon nitride film. From the same viewpoint, in one or more embodiments, the anionic constitutional unit is preferably a constitutional unit c having a structure in which at least one hydrogen atom of the aromatic ring in the main chain is substituted with a sulfonic add group (also referred to simply as a “constitutional unit c” in the following). Examples of the aromatic ring include a phenol skeleton and a naphthalene skeleton. Moreover, monomers forming the constitutional unit c may be, e.g., at least one selected from phenolsulfonic acid, nap acid, and salts thereof.

The component C may further contain a constitutional unit other than the constitutional unit c. In one or more embodiments, the constitutional unit other than the constitutional unit c may be at least one constitutional unit selected from a constitutional unit represented by the following formula (V) (also referred to simply as a “constitutional unit c1” in the Billowing) and a constitutional unit c2 represented by the Mowing formula NO (also referred to simply as a “constitutional unit c2” in the following) from the viewpoint of maintaining the polishing rate, improving the polishing selectivity, and reducing the polishing rate of the silicon nitride film and the dishing rate during overpolishing, and particularly from the viewpoint of improving the polishing selectivity.

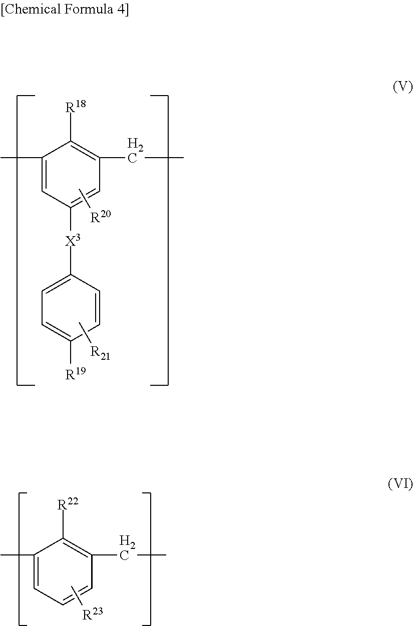

In the formula (V), R¹⁸ and R¹⁹ are the same or different and represent a hydrogen atom or —OM¹, M¹ represents at least one selected from alkali metal, alkaline earth metal, organic cation, ammonium, and a hydrogen atom, R²⁰ and R²¹ are the same or different and represent a hydrogen atom, an alkyl group, an alkoxy group, an aralkyl group, or —OM², M² represents at least one selected from alkali metal, alkaline earth metal, organic cation, ammonium, and a hydrogen atom, and X represents a bond, —CH₂—, —S—, —SO₂—, —C(CH₃)₂—, or

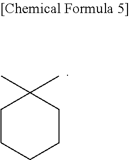

In the formula (V), R¹⁸ and R¹⁹ are preferably —OM¹, and more preferably —OH from the viewpoint of maintaining the polishing rate, improving the polishing selectivity, and reducing the polishing rate of the silicon nitride film and the dishing rate during overpolishing, and particularly from the viewpoint of improving the polishing selectivity. R²⁰ and R²¹ are preferably a hydrogen atom or an alkyl group, and more preferably a hydrogen atom or a methyl group from the viewpoint of maintaining the polishing rate and improving the polishing selectivity. X³ is preferably —SO₂— from the viewpoint of maintaining the polishing rate, improving the polishing selectivity, and reducing the polishing rate of the silicon nitride film and the dishing rate during overpolishing.

In the formula (VI), R represents a hydrogen atom or —OM³, M³ represents at least one selected from alkali metal, alkaline earth metal, organic, cation, ammonium, and a hydrogen atony, R²³ represents a hydrogen atom, an alkyl group, an alkoxy group, an aralkyl group, or —OM⁴, and M⁴ represents at least one selected from alkali metal, alkaline earth metal, organic cation, ammonium, and a hydrogen atom.

In the formula (VI), R²² is preferably —OH from the viewpoint of maintaining the polishing rate, improving the polishing selectivity, and reducing the polishing rate of the silicon nitride film and the dishing rate during overpolishing, and particularly from the viewpoint of improving the polishing selectivity. R²³ is preferably a hydrogen atom or an alkyl group from the viewpoint of maintaining the polishing rate, improving the polishing selectivity, and reducing the polishing rate of the silicon nitride film and the dishing rate during overpolishing.

The component C may be, e.g., a condensate having a structure in which at least one hydrogen atom of the aromatic ring in the main chain is substituted with a sulfonic add group, a condensate containing the constitutional unit c and a constitutional unit other than the constitutional unit c, or salts of these condensates from the viewpoint of maintaining the polishing rate, improving the polishing selectivity, and reducing the polishing rate of the silicon nitride film and the dishing rate during overpolishing, and particularly from the viewpoint of reducing the polishing rate of the silicon nitride film during overpolishing. Examples of the salts include alkali metal ions such as sodium salts, ammonium salts, and organic amine salts.

The condensate having a structure in which at least one hydrogen atom of the aromatic ring in the main chain is substituted with a sulfonic acid coup or a salt of this condensate is more preferably, at least one selected from phenolsulfonic acid, naphthalenesulfonic add, and salts thereof from the viewpoint of ma inter ling the polishing rate, improving the polishing selectivity, and reducing the polishing late of the silicon nitride film and the dishing rate during over polishing, and particularly hum the viewpoint of reducing the polishing rate of the silicon nitride film during overpolishing.

The condensate containing the constitutional unit c and a constitutional unit other than the constitutional unit c or a salt of this condensate is preferably at least one selected from condensates containing the constitutional unit c and at least one constitutional unit selected firm the constitutional unit c1 and the constitutional unit c2, and salts of these condensates from the viewpoint of maintaining the polishing rate, improving the polishing selectivity, and reducing the polishing rate of the silicon nitride film and the dishing rate during over polishing and particularly from the viewpoint of improving the polishing selectivity.

In one or more embodiments, specific examples of the component C include at least one selected from the following: a condensate of phenolsulfonic acid (PhS); a condensate of naphthalenesulfonic acid; a condensate (BisS/PhS) of bis(4-hydroxyphenyl) sulfone (BisS) and phenolsulfonic acid (PhS); a condensate of p-cresol and phenolsulfonic add (PhS); a condensate of bis(4-hydroxy-3-methylphenyl) sulfone (BSDM) and phenols it kale acid (PhS); and a condensate of phenol (Ph) and phenolsulfonic acid (PhS) from the viewpoint of maintaining the polishing rate, improving the polishing selectivity, and reducing the polishing rate of the silicon nitride film and the dishing rate during overpolishing.

When the component C is any one of the condensates containing the constitutional unite and at least one constitutional unit selected from the constitutional unit c1 and the constitutional unit c2, the molar ratio of the constitutional unite to the constitutional unit c1 or the constitutional unit c2 (constitutional unit c/constitutional unit c1 or constitutional unit c/constitutional unit c2) in all the constitutional units of the component C is preferably 50/50 to 100/0, more preferably 60/40 to 99/1, even more preferably 70/30 to 98/2, and further preferably 75/25 to 97.5/2.5 from the viewpoint of maintaining the polishing rate, improving the polishing selectivity, reducing the polishing rate of the silicon nitride film and the dishing rate during overpolishing, and the water solubility.

The component C may further contain additional constitutional units other than the constitutional units c, c1, and c2. The additional constitutional units may include, e.g., phenylphosphonic acid, hydroxyphenylphosphonic acid, and alkylphenylphosphonic add.

From the viewpoint of maintaining the polishing rate, improving the polishing selectivity, and reducing the polishing rate of the silicon nitride film and the dishing rate during overpolishing, and particularly from the viewpoint of improving the polishing selectivity the molecular weight of the component C is preferably 300 or more, more preferably 500 or more, and further preferably 700 or more. Furthermore, the molecular weight of the component C is preferably 6,000 or less, more preferably 5.500 or less and further preferably 5,000 or less. More specifically, the molecular weight of the component C is preferably 300 or more and 6,000 or less, more preferably 500 or more and 5,500 or less, and further preferably 700 or more and 5,000 or less.

The content of the component C in the polishing liquid composition of the present disclosure is preferably 0.001% by mass or more, more preferably 0.0013% by mass or more, and further preferably 0.0015% by mass or more with respect to 100% by mass of the total content of the component A, the component B, the component C, and the aqueous medium from the viewpoint of maintaining the polishing rate, improving the polishing selectivity, and reducing the polishing rate of the silicon nitride film and the dishing rate during overpolishing and particularly from the viewpoint of improving the polishing selectivity. From the same viewpoint the content of the component C is preferably 1% by mass or less, more preferably 0.2% by mass or less, and further preferably 0.1% by mass or lass with respect to 100% by mass of the total content of the component the component B, the component C, and the aqueous medium, More specifically, the content of the component C is preferably 0.001% by mass or more and 1% by mass or less, more preferably 0.0013% by mass or more and 0.2% by mass or less, and further preferably 0.0015% by mass or more and 0.1% by mass or less with respect to 100% by mass of the total content of the component A, the component B, the component C, and the aqueous medium. When the component C includes a combination of two or more types of condensates, the content of the component C is the total content of the two or more types of condensates.

The mass ratio B/C of the component B to the component C (content of component B/content of component C) in the polishing liquid composition of the present disclosure is preferably 0.1 or more, more preferably 0.5 or more, and further preferably 1 or more from the viewpoint of maintaining the polishing rate, improving the polishing selectivity, and reducing the polishing rate of the silicon nitride film and the dishing rate during overpolishing. From the same viewpoint the mass ratio B/C is preferably 20 or less, more preferably 15 or less, and further preferably 10 or less. More specifically, the mass ratio BC is preferably 0.1 or more and 20 or less, more preferably 0.5 or more and 15 or less, and further preferably 1 or more and 10 or less.

[Aqueous Medium]

Examples of the aqueous medium contained in the polishing liquid composition of the present disclosure include water such as distilled water, ion-exchanged water pure water, and ultrapure water and a mixed solvent of water and a solvent. The solvent may be any solvent that can be mixed with water (e.g., alcohol such as ethanol). When the aqueous medium is a mixed solvent of water and a solvent, the ratio of water to the total mixed medium may be any value that does not impair the effects of the present disclosure, and is preferably e.g., 95% by mass or more, more preferably 98% by mass or more, and further preferably substantially 100% by mass in terms of economy. The aqueous medium is preferably water, more preferably ion exchanged water or ultrapure water, and further preferably ultrapure water in terms of the surface cleanliness of a substrate to be polished. The content of the aqueous medium in the polishing liquid composition of the present disclosure may be the remainder obtained by subtracting the component A, the component B, and optional components that would be added as needed (which will be described later) from the amount of the polishing liquid composition.

[Compound (Component D) Having Group Represented by Formula (VII)]

In one or more embodiments, the polishing liquid composition of the present disclosure may further contain a compound having a group represented by the following formula (VII) (also referred to simply as a “component D” in the following) hum the viewpoint of maintaining the polishing rate and further improving the polishing selectivity. When the polishing liquid composition of the present disclosure further contains the component D, the component D is bound to the component C to improve the strength and thickness of a protective film that is to be formed on the polishing stopper film, and thus the polishing rate of the polishing stopper film can be further reduced. In this case, the component B has the effect of improving the polishing rate of the object to be polished (i.e., the silicon oxide film) and the components C, D have the effect of reducing the polishing rate of the polishing stopper film. Since these effects are exerted individually, it may be possible to further improve the polishing selectivity and also to maintain the polishing rate of the silicon ode film. The component D may be of one type or two or more different types. The component D is preferably water soluble and has a solubility of preferably 0.5 g/100 mL or more in water (at 20° C.).

—[(CHX)ₚ—O]_{q}— (VII)

In the formula (VII), X represents a hydrogen atom or OH, p represents a number of 2 or more and 5 or less, and q represents a number of 5 or more and 10,000 or lass. If p is 2 or more, X's may be the same or different.

In the formula (VII), p is 2 or more and 5 or less, preferably 2 or more and 4 or less, more preferably 2 or more and 3 or less, and further preferably 2 from the viewpoint of maintaining the polishing rate, further improving the polishing selectivity, and water solubility. From the same viewpoint, q is 5 or more and 10,000 or less, preferably 7 or more and 8,000 or less, more preferably 10 or more and 5,000 or less, and further preferably 20 or more and 1,000 or less.

Examples of the group represented by the formula (VII) include an ethylene oxide group, a —CH₂—CHOH—CH₂—O— group, a propylene oxide group, and a butylene oxide group. Specific examples of the component D include polyethylene glycol, polypropylene glycol, and polyglycerol. The component D is preferably polyethylene glycol or polyglycerol from the viewpoint of maintaining the polishing rate and further improving the polishing selectivity.

From the viewpoint of maintaining the polishing rate and further improving the polishing selectivity, the molecular weight of the component D is preferably 500 or more, more preferably 1,000 or more, and further preferably 1,500 or more. Furthermore, the molecular weight of the component D is preferably 100,000 or less more preferably 75,000 or less, and further preferably 50,000 or less. More specifically in one or mom embodiments the molecular weight of the component D is preferably 500 or more and 100,000 or less, more preferably 1,000 or more and 75,000 or less, and further preferably 1,500 or more and 53,000 or less. In another one or more embodiments, the molecular weight of the component D is preferably 500 or more and 50,000 or less.

When the polishing liquid composition of the present disclosure contains the component D, the content of the component D in the polishing liquid composition of the present disclosure is preferably 0.01% by mass or more, more preferably 0.025% by mass or more, and further preferably 0.05% by mass or more with respect to 100% by mass of the total content of the component A, the component B, the component C, the component D, and the aqueous medium from the viewpoint of maintaining the polishing rate and further improving the polishing selectivity. From the me viewpoint, the content of the component D is preferably 1% by mass or less, more preferably 0.75% by mass or less, and further preferably 0.5% by mass or less with respect to 100% by mass of the total content of the component A, the component B, the component C, the component ID, and the aqueous medium, More specifically the content of the component D is preferably 0.01% by mass or more and 1% by mass or less, more preferably 0.025% by mass or more and 0.75% by mass or less, and further preferably 0.05% by mass or more and 0.5% by mass or less with respect to 100% by mass of the total content of the component A, the component B, the component C, the component D, and the aqueous medium. When the component D includes a combination of two or more types of compounds, the content of the component D is the total content of the two or more types of compounds,

[Other Components]

The polishing liquid composition of the present disclosure may further contain other components such as a pH adjustor, polymers other than the components B to D, a surfactant, a thickener, a dispersant, a rust preventive, an antiseptic, a basic substance, a polishing rate improver, a silicon nitride film polishing inhibitor, and a polysilicon film polishing inhibitor. When the polishing liquid composition of the present disclosure further contains other components, from the viewpoint of improving the polishing rate, the content of the other components in the polishing liquid composition is preferably 0.001% by mass or more, more preferably 0.0025% by mass or more, and further preferably 001% by mass or more. Furthermore, the content of the other components is preferably 1% by mass or less, more preferably 0.5% by mass or less, and further preferably 0.1% by mass or less. More specifically, the content of the other components is preferably 0.001% by mass or more and 1% by mass or leas, more preferably 0.0025% by mass or more and 0.5% by mass or less, and further preferably 0.01% by mass or more and 0.1% by mass or less.

[Polishing Liquid Composition]

The polishing liquid composition of the present disclosure can be produced by a production method that includes blending, e.g., the component A, the component B the component C, and the aqueous medium, and the optional components (the component D and other components) as desired, with a known method. For example, the polishing liquid composition of the present disclosure may be produced by blending at least the component A, the component B, the component C, and the aqueous medium. In the present disclosure, the term “blend” may include mixing the component A the component B the component C, and the aqueous medium, and the optional components (the component D and other components) as needed, simultaneously or in sequence. They can be mixed in any order. The blending can be performed, e.g., with a mixer such as a homomixer, a homogenizer, an ultrasonic disperser, or a wet ball mill. The blending amount of each component in the production method of the polishing liquid composition of the present disclosure may be the same as the content of each component in the polishing liquid composition, as described above.

An embodiment of the polishing liquid composition of the present disclosure may be either a so-called one-part or two-part polishing liquid composition. The one-part polishing liquid composition is supplied to the market with all the components being mixed together. On the other hand, the components of the two-part polishing liquid composition are mixed at the time of use. An embodiment of the two-part polishing liquid composition may include a first solution containing the component A and a second solution containing the component B and the component C. The first solution and the second solution may be mixed at the time of use. In this case, the first solution and the second solution may be mixed just before application to the surface of an object to be polished. Alternatively, the first solution and the second solution may be supplied separately and mixed on the surface of a substrate to be polished. Each of the first solution and the second solution may contain the above optional components (the component D and other components) as needed.

From the viewpoint of improving the polishing rate; the pH of the polishing liquid composition of the present disclosure is preferably 3.5 or more, more preferably 4 or more, and further preferably 5 or more. Furthermore, the pH of the polishing liquid composition is preferably 9 or less more preferably 8.5 or less, and further preferably 8 or less. More specifically, the pH of the polishing liquid composition is preferably 3.5 or more and 9 or less, more preferably 4 or more and 8.5 or less, and further preferably 5 or more and 8 or less. In the present disclosure, the pH of the polishing liquid composition is a value at a temperature of 25° C. and can be measured with a pH meter. Specifically, the pH of the polishing liquid composition can be measured by a method as described in Examples.

The “content of each component in the polishing liquid composition” of the present disclosure means the amount of each component at the time of polishing, i.e., at the time the polishing liquid composition starts to be used for polishing. The polishing liquid composition of the present disclosure may be concentrated so as not to impair the stability and stored and supplied in the concentrated state. This can reduce the production and trams sortation costs. If necessary the concentrated solution may be appropriately diluted with water and used in the polishing process. The dilution factor is preferably 5 to 100.

[Film to be Polished]

The film to be polished with the polishing liquid composition of the present disclosure may be, e.g., a silicon oxide film. Thus the polishing liquid composition of the present disclosure can be used in the process that requires polishing of the silicon oxide film. In one or more embodiments, the polishing liquid composition of the present disclosure can be suitably used for the following purposes: polishing of a silicon oxide film in the process of forming an element isolation structure of a semiconductor substrate; polishing of a silicon oxide film in the process of forming an interlayer insulation film; polishing of a silicon oxide film in the process of fairing embedded metal wiring; or polishing of a silicon oxide film in the process of firming an embedded capacitor. In another one or more embodiments the polishing liquid composition of the present disclosure can be suitably used for the production of a three-dimensional semiconductor device such as a three-dimensional NAND flash memory,

[Polishing Liquid Kit]

In another aspect, the present disclosure relates to a kit for producing the polishing liquid composition of the present disclosure (also referred to as a “polishing liquid kit of the present disclosure” in the following).

An embodiment of the polishing liquid kit of the present disclosure may be, e.g., a polishing liquid kit (two-part polishing liquid composition) including a ceria dispersion (first solution) and an additive aqueous solution (second solution) so that they are not mixed with each other. The ceria dispersion contains the component A and the aqueous medium, and the additive aqueous solution contains the component B and the component C. The ceria dispersion (first solution) and the additive aqueous solution (second solution) are mixed at the time of use, and the mixed solution may be diluted with the aqueous medium as needed. The aqueous medium contained in the coria dispersion (first solution) may correspond to the whole or part of the amount of water used for the preparation of the polishing liquid composition. The additive aqueous solution (second solution) may contain a part of the aqueous medium used for the preparation of the polishing liquid composition Each of the ceria dispersion (first solution) and the additive aqueous solution (second solution) may contain the above optional components (the component D and other components) as needed.

The polishing liquid kit of the present disclosure can provide a polishing liquid composition capable of improving the polishing rate of a silicon oxide film.

[Method for Producing Semiconductor Substrate]

In one aspect, the present disclosure relates to a method from producing a semiconductor substrate (also referred to as a “production method of a semiconductor substrate of the present disclosure” in the following). The method includes polishing a film to be polished with the polishing liquid composition of the present disclosure (also referred to as a “polishing process using the polishing liquid composition of the present disclosure” in the following). The production method of a semiconductor substrate of the present disclosure can improve the polishing rate of a silicon oxide film, and thus can be effective in efficiently producing a semiconductor substrate.

A specific example of the production method of a semiconductor substrate of the present disclosure is as follows. First, a silicon substrate is exposed to oxygen in an oxidation furnace so that a silicon dioxide layer is grown on the surface of the silicon substrate. Then, a polishing stopper film such as a silicon nitride (Si₃N₄) film or a polysilicon film is formed on the silicon dioxide layer by, e.g., a CVD (chemical vapor deposition) method. Next, a trench is formed by a photolithography technique in a substrate that includes the silicon substrate and the polishing stopper film provided on one of the main surfaces of the silicon substrate, e.g., in a substrate that includes the silicon substrate and the polishing stopper film provided on the silicon dioxide Layer of the silicon substrate. Subsequently a silicon oxide (SiO₂) film (i.e., a film to be polished) is formed to fill the trench by, e.g., a CND method using a silane gas and an oxygen gas. Thus, the polishing stopper film is covered with the film to be polished (the silicon oxide film), resulting in a substrate to be polished. Because of the formation of the silicon oxide film, the trench is filled with silicon oxide of the silicon oxide film, and the since of the polishing stopper film that is opposite to the other surface facing the silicon substrate is covered with the silicon oxide film. Consequently, the surface of the silicon oxide film that is opposite to the other surface facing the silicon substrate has a step according to the unevenness of the underlying layer. Then, the silicon oxide film is polished by a CMP method until at least the surface of the polishing stopper film that is opposite to the other surface facing the silicon substrate is exposed. More preferably, the silicon oxide film is polished until the surface of the silicon oxide film is flush with the surface of the polishing stopper film. The polishing liquid composition of the present disclosure can be used in this polishing process of the CMP method. The silicon oxide film has projections and recesses according to the unevenness of the underlying layer, and the width of a projection may be, e.g., 0.5 μm or more and 5,000 μm or less and the width of a recess may be, e.g., 0.5 μm or more and 5,000 μm or

In the polishing process of the CMP method, the surface of the substrate to be polished is brought into contact with a polishing pad, and the substrate and the polishing pad are moved relative to each other while the polishing liquid composition of the present disclosure is being, supplied to the contact area between them, so that the uneven portion of the surface of the substrate is planarized.

In the production method of a semiconductor substrate of the present disclosure, another insulation film may be formed between the silicon dioxide layer of the silicon substrate and the polishing stopper film. Alternatively, another insulation film may be formed between the film to be polished (e.g., the silicon oxide film) and the polishing stopper film (e.g., the silicon nitride film).

In the polishing process using the polishing liquid composition of the present disclosure, the rotation speed of the polishing pad may be, ag, 30 to 200 rpm/min, the rotation speed of the substrate to be polished may be, e.g., 30 to 200 rpm/min, the polishing load set in the polishing device including the polishing pad may be, e.g., 20 to 500 g weight/cm², and the supply rate of the polishing liquid composition may be, e.g., 10 to 500 mL/min or less. When the polishing liquid composition is a two-part polishing liquid composition, the supply rate (or the amount of supply) of each of the first solution and the second solution can be adjusted to control the polishing rate of the film to be polished, the polishing rate of the polishing stopper film, and the ratio of the polishing rate of the film to be polished to the polishing rate of the polishing stopper film (i.e., the polishing selectivity).

In the polishing process using the polishing liquid composition of the present disclosure, the polishing rate of the film to be polished (the silicon oxide film) is preferably 50 nm/min or more, more preferably 80 nm/min or more, and further preferably 90 nm/min or more from the viewpoint of improving the productivity.

[Polishing Method]

In one aspect, the present disclosure relates to a polishing method that includes polishing a film to be polished with the polishing liquid composition of the present disclosure (also referred to as a “polishing method of the present disclosure” in the following). The polishing method of the present disclosure can improve the polishing rate of the silicon oxide film, and thus can be effective in improving the productivity of a high-quality semiconductor substrate. The specific polishing method and conditions may be the same as those of the production method of a semiconductor substrate of the present disclosure, as described above.

### EXAMPLES

Hereinafter, the present disclosure will be described in detail by way of examples. However, the present disclosure is not limited to the following examples.

1. Water-Soluble Polymers B1 to B7

The following materials were used for water-soluble polymers B1 to B7, as shown in Tables 2 to 6.

[Water-Soluble Polymer B1]

A water-soluble polymer B1 (component B) was a polymer of MPC (Lipdidure-HM, trade name, manufactured by NOF CORPORATION). The weight average molecular weight, of the water-soluble polymer B1 was 100,000.

[Water-Soluble Polymer B2]

A water-soluble polymer B2 (component B) was a copolymer of MPC and BMA (Lipidure-PMB, trade name, manufactured by NOF CORPORATION), The molar ratio (MPC/BMA) of the constitutional units in the water-soluble polymer 132 was 80120, and the weight average molecular weight of the water-soluble polymer B2 was 600,000.

[Water-Soluble Polymer B3]

A water-soluble polymer B3 (component B) was a copolymer of MPC and SMA (Lipidure-S, trade name, manufactured by NOF CORPORATION). The molar ratio (MPC/SMA) of the constitutional units in the water-soluble polymer B3 was 80/20, and the weight average molecular weight of the water-soluble polymer B3 was 100,000.

[Water Soluble Polymer B4]

A water-soluble polymer B4 (component B) was a copolymer of MPC and BzMA (manufactured by NOF CORPORATION). The molar ratio (MPC/BzMA) of the constitutional units in the water-soluble polymer 134 was 80/20, and the weight average molecular weight of the water-soluble polymer B4 was 100,000.

[Production Example of Water-Soluble Polymer B5]

In a 300 mL four necked eggplant flask was placed 20.0 g of ethanol, and the temperature was raised to 80° C. Then, a solution containing a mixture of 10.0 g of MPC (manufactured by Tokyo Chemical Industry Co., Ltd), 0.94 g of 1-vinyl-2-pyrrolidone (VP) (manufactured by FUJIFILM Wako Pure Chemical Corporation), and 20.0 g of ethanol and a solution containing a mixture of 0.042 g of 2,2′-azobis(isobutyronitrile) (manufactured by Wako Pure Chemical Industries Ltd.) and 10.0 g of ethanol were separately added drop wise to the flask for 2 hours and polymerized. After aging for 4 hours, the solvent was distilled off under reduced pressure and replaced with water, so that a polymer aqueous solution containing a water-soluble polymer B5 (i.e., a copolymer of MPC and VP) (component 13) was obtained. The molar ratio (MPC/VP) of the constitutional units in the water-soluble polymer B5 was 80/20, and the weight average molecular weight of the water-soluble polymer 1:35 was 100,000.

[Production Example of Water-Soluble Polymer B5]

In a 300 mL four-necked eggplant flask was placed 20.0 g of ethanol, and the temperature was raised to 80° C. Then, a solution containing a mixture of 10.0 g of MPC (manufactured by Tokyo Chemical Industry Co., Ltd.), 0.99 g of α-methyl styrene (αMSt) (manufactured by FUJIFILM Wako Pure Chemical Corporation), and 20.0 g of ethanol and a solution containing a mixture of 0.042 g of 2,2-azobis(isobutyronitrile) (manufactured by Wako Pure Chemical Industries Ltd.) and 10.0 g of ethanol were separately added drop-wise to the flask for 2 hours and polymerized. After aging for 4 hours the solvent was distilled off under reduced pressure and replaced with water, so that a polymer aqueous solution containing a water-soluble polymer B6 (i.e., a copolymer of MPC and αMSt) (component B) was obtained. The molar ratio (MPC/αMSt) of the constitutional units in the water-soluble polymer B6 was 80/20, and the weight average molecular weight of the water-soluble polymer B6 was 100,000.

[Water-Soluble Polymer B7]

A water-soluble polymer B7 (non-component B) was a polymer of vinylpyrrolidone (PVP) (PVP K-60 trade name, manufactured by ISP (International Specialty Products Inc.)) The weight average molecular weight of the water-soluble polymer B7 was 400,000.

2. Anionic Compounds C1 to C10

The following materials were used for anionic compounds C1 to C10, as shown in Tables 2 to 6.

C1: BisS/PhS [condensate of bis(4-hydroxyphenyl) sulfone and phenolsulfonic acid, molar ratio (BisS/Phs): 2.5/97.5, manufactured by Konishi Chemical Inc Co., Ltd., weight average molecular weight: 1,300]

C2: p-cresol/PhS [condensate of p-cresol and phenolsulfonic acid, molar ratio (p-cresol/Phs): 10/90, manufactured by Konishi Chemical Inc. Co., Ltd., weight average molecular weight: 5,000]

C3: BSDM/PhS [condensate of bis(4-hydroxy-3-methylphenyl) sulfone and phenolsulfonic acid, molar ratio (BSDM/Phs): 10/90, manufactured by Konishi Chemical Inc. Co. Ltd., weight average molecular weight: 5,000]

C4: Ph/PhS [condensate of phenol and phenolsulfonic acid, molar ratio (Ph/Phs): 20/80, manufactured by Konishi Chemical Inc Co, Ltd., weight average molecular weight: 5,000]

C5: PhS [condensate of phenolsulfonic acid, manufactured by Konishi Chemical Inc. Co., Ltd., weight average molecular weight: 2,000]

C6: condensate of naphthalenesulfonic acid [DEMOLN, trade name, manufactured by Kao Corporation, weight average molecular weight: 3,000]

C7: polyacrylic acid. [A-210, trade name, manufactured by TOAGOSEI CO., LTD., weight average molecular weight: 3,000]

C8: PSS [polystyrene sulfonate, PS-1, trade name, manufactured by Tosoh Organic Chemical Co., Ltd., weight average molecular weight: 21,000]

C9: BisS/PhS [condensate of bis(4-hydroxyphenyl) sulfone and phenolsulfonic acid, molar ratio (BisS/Phs): 50/50 manufactured by Konishi Chemical Inc. Co., Ltd., weight average molecular weight 1,300]

C10: AA/AMPS [acrylic acid/2-acrylamide-2-methylpropane sulfonic acid copolymer, molar ratio (AA/AMPS): 80/20, weight average molecular weight: 1,800, manufactured by TOAGOSEI CO., LTD.] (non-component C)

TABLE 1
Table 1

| | C1 (component C) | C2 (component C) | C3 (component C) |
|---|---|---|---|
| Type | BisS/PhS | p-cresol/PhS | BSDM/PhS |
| Structure | 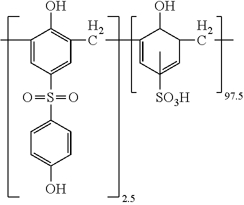 | 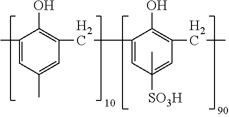 | 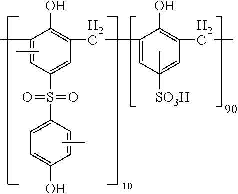 |
| Molecular | 1,300 | 5,000 | 5,000 |
| weight | | | |

| | C4 (component C) | C5 (component C) | C6 (component C) |
|---|---|---|---|
| Type | Ph/PhS | PhS | naphthalenesulfonic acid |
| Structure | 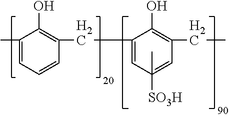 | 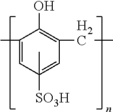 | 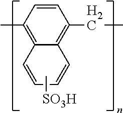 |
| Molecular | 5,000 | 2,000 | 3,000 |
| weight | | | |

| | C7 (non-component C) | C8 (non-component C) | C9 (component C) |
|---|---|---|---|
| Type | polyacrylic acid | PSS | BisS/PhS |
| Structure | 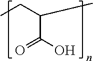 | 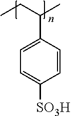 | 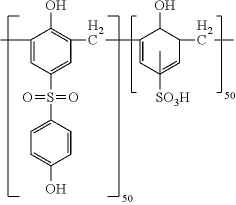 |
| Molecular | 3,000 | 21.000 | 1,300 |
| weight | | | |

3. Compounds D1 to D5 Having Group Represented by —[(CHX)ₚ—O]_{q}—

The following materials were used for compounds D1 to D5 having a group represented by —[(CHX)ₚ—O]_{q}—, as shown in Tables 5 to 6.

(Component D)

D1: PEG [polyethylene glycol molecular weight: 20,000, manufactured by FUJIFILM Wako Pure Chemical Corporation]

D2: PEG [polyethylene glycol, molecular weight: 1,540, manufactured by FUJIFILM Wako Pure Chemical Corporation]

D3 PEG [polyethylene glycol, molecular weight: 4,000, manufactured by FUJIFILM Wako Pure Chemical Corporation]

D4: PEG [polyethylene glycol, molecular weight: 8,000, manufactured by Sigma-Aldrich]

D5: 50-mer of polyglycerol [molecular weight: 4,600, manufactured by Daicel Corporation]

4. Preparation of Polishing Liquid Composition

### Examples 1 to 22, Comparative Examples 1 to 14

Cerium oxide particles [crushed coria, average primary particle size: 28.6 nm, BET specific surface area: 29.1 m²/g surface potential: 80 mV] (component A), a water-soluble polymer (component B), an anionic compound (component C or non-component C), and water were mixed together to prepare polishing liquid compositions of Examples 1 to 22 and Comparative Examples 1 to 14. Tables 2 to 4 show the content OA by mass, active part) of each component in a polishing liquid composition. The content of water was the remainder obtained by subtracting the component A, the component B or non-component B, and the component C or non-component C from the amount of the polishing liquid composition. The pH was adjusted by using ammonia or nitric acid.

### Examples 23 to 51, Comparative Examples 15 to 26

Cerium oxide particles [crushed ceria, average primary particle size: 28.6 nm, BET specific surface area: 29.1 m²/g, surface potential: 80 mV] (component A), a water-soluble polymer (component B), an anionic compound (component C), a compound having a group represented by —[(CHX)ₚ—O]_{q}— (component D), and water were mixed together to prepare polishing liquid compositions of Examples 23 to 51 and Comparative Examples 15 to 26. Tables 5 to 6 show the content (% by mass, active part) of each component in a polishing liquid composition. The content of water was the remainder obtained by subtracting the component A the component B, the component C or non-component C, and the component 1) from the amount of the polishing liquid composition. The pH was adjusted by using ammonia or nitric acid.

5. Method for Measuring Each Parameter

(1) pH of Polishing Liquid Composition

The value of the polishing liquid composition at 25° C. was measured with a pH meter (“HW-41K” manufactured by DKK-TOA CORPORATION). Specifically the pH value was obtained 1 minute after the electrode of the pH meter was immersed in the polishing liquid composition. Tables 2 to 6 show the results.

(2) Average Primary Particle Size of Cerium Oxide Particles (Component A)

The average primary particle size (nm) of the cerium oxide particles (component A) was calculated by using a specific surface area S (m²/g) that was determined by the following BET (nitrogen adsorption) method, where the true density of the cerium oxide particles was set to 7.2 g/cm³.

(3) BET Specific Surface Area of Cerium Oxide Particles (Component A)

The specific surface area was measured in the following manner. A dispersion of the cerium oxide particles was dried with hot air at 120° C. for 3 hours and then finely pulverized in an agate mortar, providing a sample. The sample was dried in an atmosphere at 120° C. for 15 minutes immediately before measuring the specific surface area. Then, the specific surface area was measured by the nitrogen adsorption method (BET method) using a specific surface area measuring device, (Micromeritics Automatic Surface Area Analyzer “FlowSorb III 2305” manufactured by Shimadzu Corporation).

(4) Surface Potential of Cerium Oxide Particles (Component A)

The surface potential (mV) of the cerium oxide particles was measured with a surface potential measuring device (“ZetaProbe” manufactured by Kyowa Interface Science Co., Ltd.). The cerium oxide concentration was adjusted to 0.15% by using ultrapure water. Then, the solution was introduced into the surface potential measuring device, and the surface potential was measured under the conditions that the particle density was 7.13 g/ml and the particle dielectric constant was 7. The measurement was carried out three times, and the average of the measured values was used as the measurement result.

6. Evaluation of Polishing Liquid Composition (Examples 1 to 22, Comparative Examples 1 to 14)

[Production of Test Piece]

A silicon oxide film (blanket film) with a thickness of 2,000 urn was formed on one side of a silicon wafer by a TEOS-plasma. CVD method, A square piece of 40 mm×40 mm was cut from the silicon wafer having the silicon oxide film, providing a silicon oxide film test piece (blanket substrate).

Similarly; a silicon nitride film (blanket film) with a thickness of 70 nm was formed on one side of a silicon wafer by a CVD method, A square piece of 40 min×40 mm was cut from the silicon wafer having the silicon nitride film, providing a silicon nitride film test piece (blanket substrate).

[Polishing Rate of Silicon Oxide Film (Film to be Polished)]

A polishing device was “TR15M-TRK1” manufactured by Techno Rise Corporation, which has a surface plate diameter of 380 mm. A polishing pad was a hard urethane pad “IC-1000/Suba 400” manufactured by Nitta Haas Inc. The polishing pad was attached to the surface plate of the polishing device. The silicon oxide film test piece was set in a holder and the holder was placid on the polishing pad with the surface of the test piece, on which the silicon oxide film had been formed; facing down (i.e., with the silicon oxide film lacing the polishing pad). Moreover, a weight was put on the holder so that the load applied to the test piece was 300 g weight/cm². The silicon oxide film test piece was polished by rotating each of the surface plate and the holder in the same direction at 90 rpm/min for 1 minute while the polishing liquid composition was dropped at a rate of 50 mL/min on the center tithe surface plate to which the polishing pad was attached. Then, the polished test piece was cleaned with ultrapure water and dried. The resulting, silicon oxide film test piece was used as a measuring object for an optical interference film thickness measuring device, as will be described below.

The thickness of the silicon oxide film was measured before and after polishing with the optical interference film thickness measuring device (“VM-1230” manufactured by SCREEN Semiconductor Solutions Co., The polishing rate of the silicon oxide film was calculated by the fallowing formula. Tables 2 to 4 show the results.

Polishing rate of silicon oxide film (Å/min)=[thickness of silicon oxide film before polishing (Å)−thickness of silicon oxide film after polishing (Å)]/polishing time (min)

[Polishing Rate of Silicon Nitride Film (Polishing Stopper Film)]

The silicon nitride film was polished and the thickness of the silicon nitride film was measured in the same manner as the measurement of the polishing rate of the silicon oxide film, as described above, except that the silicon nitride film test piece was used instead of the silicon oxide film test piece. The polishing rate of the silicon nitride film was calculated by the Mowing formula. Tables 2 to 4 show the results.

Polishing rate of silicon nitride film (λ/min)=[thickness of silicon nitride film before polishing (Å)−thickness of silicon nitride film after polishing (Å)]/polishing time (min)

[Polishing Selectivity (Ratio of Polishing Rate)]

The ratio of the polishing rate of the silicon oxide film to the polishing rate of the silicon nitride film was calculated by the following formula as a ratio of polishing rate. Tables 2 to 4 show the results. The higher the polishing selectivity the larger the ratio of polishing rate.

Ratio of polishing rate=polishing rate of silicon oxide film (Å/min)/polishing rate of silicon nitride film (Å/min)

TABLE 2

| | Polishing liquid composition | | | | | | |
|---|---|---|---|---|---|---|---|
| | Cerium | | | | | | |
| | oxide | | | | Anionic condensation product | | |
| | particle | Water-soluble polymer | | | (component C) | | |
| | (component | (component B) | | | | | Content |
| | A) | | Type of | | | Type of | ratio of |
| | Content | | constituent | Content | | constituent | constituent |
| Table 2 | (mass %) | Type | monomer | (mass %) | Type | monomer | monomer |
| Ex. 1 | 0.15 | B1 | MPC | 0.01 | C1 | BisS/PhS | 2.5/97.5 |
| Ex. 2 | 0.15 | B1 | MPC | 0.01 | C1 | BisS/PhS | 2.5/97.5 |
| Ex. 3 | 0.15 | B1 | MPC | 0.01 | C1 | BisS/PhS | 2.5/97.5 |
| Ex. 4 | 0.15 | B1 | MPC | 0.01 | C1 | BisS/PhS | 2.5/97.5 |
| Ex. 5 | 0.15 | B1 | MPC | 0.01 | C2 | p-cresol/PhS | 10/90 |
| Ex. 6 | 0.15 | B1 | MPC | 0.01 | C3 | BSDM/PhS | 10/90 |
| Ex. 7 | 0.15 | B1 | MPC | 0.01 | C4 | Ph/PhS | 20/80 |
| Ex. 8 | 0.15 | B1 | MPC | 0.01 | C5 | PhS | 0/100 |
| Ex. 9 | 0,15 | B1 | MPC | 0.01 | C6 | naphthalene- | 0/100 |
| | | | | | | sulfonic acid | |
| Ex. 10 | 0.15 | B1 | MPC | 0.01 | C1 | BisS/PhS | 2.5/97.5 |
| Ex. 11 | 0.15 | B1 | MPC | 0.01 | C1 | BisS/PhS | 2.5/97.5 |
| Ex. 12 | 0.15 | B1 | MPC | 0.01 | C1 | BisS/PhS | 2.5/97.5 |
| Ex. 13 | 0.15 | B1 | MPC | 0.01 | C1 | BisS/PhS | 2.5/97.5 |
| Comp. Ex. 1 | 0.15 | — | — | — | — | — | — |
| Comp, Ex. 2 | 0.15 | B1 | MPC | 0.01 | — | — | — |
| Comp. Ex. 3 | 0.15 | — | — | — | C1 | BisS/PhS | 2.5/97.5 |
| Comp. Ex. 4 | 0.15 | B1 | MPC | 0.01 | C7 | polyacrylic acid | 0/100 |
| | | | | | | (non-component C) | |
| Comp, Ex. 5 | 0.15 | B1 | MPC | 0.01 | C8 | PSS | 0/100 |
| | | | | | | (non-component C) | |
| Comp. Ex. 6 | 0.15 | B1 | MPC | 0.01 | PhS monomer | | — |
| Comp, Ex. 7 | 0.15 | B1 | MPC | 0.01 | PhS monomer | | — |
| Comp. Ex. 8 | 0.15 | B7 | PVP | 0.01 | — | — | — |

| | Polishing liquid composition | | | | | Polishing |
|---|---|---|---|---|---|---|
| | Anionic | | | | | selectivity |
| | condensation | | | Polishing rate | | Ratio of |
| | product | | | Silicon | Silicon | polishing rate |
| | (component C) | | | oxide | nitride | (silicon oxide |
| | Molecular | Content | pH | film | film | film/silicon |
| Table 2 | weight | (mass %) | (25° C.) | Å/min | Å/min | nitride film) |
| Ex. 1 | 1300 | 0.002 | 5 | 4580.6 | 138 | 33.1 |
| Ex. 2 | 1300 | 0.003 | 5 | 4191.2 | 104 | 40.3 |
| Ex. 3 | 1300 | 0.004 | 5 | 3503 | 80.4 | 43.6 |
| Ex. 4 | 1300 | 0.005 | 5 | 3482.8 | 78 | 44.7 |
| Ex. 5 | 5000 | 0.0015 | 5 | 3252.8 | 72 | 45.2 |
| Ex. 6 | 5000 | 0.002 | 5 | 5215.8 | 156.8 | 33.3 |
| Ex. 7 | 5000 | 0.002 | 5 | 3192.6 | 114 | 28.0 |
| Ex. 8 | 2000 | 0.002 | 5 | 5789.4 | 126.4 | 45.8 |
| Ex. 9 | 3000 | 0.003 | 5 | 3340.6 | 99.4 | 33.6 |
| Ex. 10 | 1300 | 0.003 | 4 | 5712.8 | 204.4 | 27.9 |
| Ex. 11 | 1300 | 0.003 | 6 | 6253.4 | 174.8 | 35.8 |
| Ex. 12 | 1300 | 0.003 | 7 | 6260.6 | 165.6 | 37.8 |
| Ex. 13 | 1300 | 0.003 | 8 | 6799.4 | 166.4 | 40.9 |
| Comp. Ex. 1 | — | — | 5 | 2219.6 | 392.8 | 5.7 |
| Comp, Ex. 2 | — | — | 5 | 4423.4 | 843.6 | 5.2 |
| Comp. Ex. 3 | 1300 | 0.003 | 5 | 841.8 | 119.2 | 7.1 |
| Comp. Ex. 4 | 3000 | 0.003 | 5 | 5149.3 | 517 | 10.0 |
| Comp, Ex. 5 | 10000 | 0.002 | 5 | 5529.8 | 576 | 9.6 |
| Comp. Ex. 6 | — | 0.003 | 5 | 5293.6 | 993.2 | 5.3 |
| Comp, Ex. 7 | — | 0.005 | 5 | 5141 | 1048 | 4.9 |
| Comp. Ex. 8 | — | — | 5 | 1109.8 | 261.9 | 4.2 |

TABLE 3

| | Polishing liquid composition | | | | | | |
|---|---|---|---|---|---|---|---|
| | Cerium | | | | | | |
| | oxide | | | | Anionic condensation product | | |
| | particle | Water-soluble polymer | | | (component C) | | |
| | (component | (component B) | | | | | Content |
| | A) | | Type of | | | Type of | ratio of |
| | Content | | constituent | Content | | constituent | constituent |
| Table 3 | (mass %) | Type | monomer | (mass %) | Type | monomer | monomer |
| Ex. 14 | 0.15 | B2 | MPC/BMA | 0.01 | C1 | BisS/PhS | 2.5/97.5 |
| Ex. 15 | 0.15 | B3 | MPC/SMA | 0.01 | C1 | BisS/PhS | 2.5/97.5 |
| Ex. 16 | 0.15 | B4 | MPC/BzMA | 0.01 | C1 | BisS/PhS | 2.5/97.5 |
| Ex. 17 | 0.15 | B5 | MPC/VP | 0.01 | C1 | BisS/PhS | 2.5/97.5 |
| Ex. 18 | 0.15 | B6 | MPC/aMSt | 0.01 | C1 | BisS/PhS | 2.5/97.5 |
| Comp. Ex. 9 | 0.15 | B2 | MPC/BMA | 0.01 | — | — | — |
| Comp, Ex. 10 | 0.15 | B3 | MPC/SMA | 0.01 | — | — | — |
| Comp. Ex. 11 | 0.15 | B4 | MPC/BzMA | 0.01 | — | — | — |
| Comp. Ex. 12 | 0.15 | B5 | MPC/VP | 0.01 | — | — | — |
| Comp. Ex. 13 | 0.15 | B6 | MPC/aMSt | 0.01 | — | — | — |
| | | Polishing liquid composition | | | | | Polishing |
| | | Anionic | | | | | selectivity |
| | | condensation | | | Polishing rate | | Ratio of |
| | | product | | | Silicon | Silicon | polishing rate |
| | | (component C) | | | oxide | nitride | (silicon oxide |
| | | Molecular | Content | pH | film | film | film/silicon |
| | Table 3 | weight | (mass %) | (25° C.) | Å/min | Å/min | nitride film) |
| | Ex. 14 | 1300 | 0.003 | 5 | 2903 | 82.8 | 35.1 |
| | Ex. 15 | 1300 | 0.003 | 5 | 2598.2 | 21.6 | 120.3 |
| | Ex. 16 | 1300 | 0.003 | 5 | 4381.4 | 176 | 24.9 |
| | Ex. 17 | 1300 | 0.003 | 5 | 4036 | 64.8 | 62.3 |
| | Ex. 18 | 1300 | 0.003 | 5 | 3477.6 | 52.4 | 66.4 |
| | Comp. Ex. 9 | — | — | 5 | 2918.8 | 426.8 | 6.8 |
| | Comp, Ex. 10 | — | — | 5 | 3023.4 | 327.2 | 9.2 |
| | Comp. Ex. 11 | — | — | 5 | 3651.8 | 718.4 | 5.1 |
| | Comp. Ex. 12 | — | — | 5 | 4400.4 | 438.8 | 10.0 |
| | Comp. Ex. 13 | — | — | 5 | 3195.6 | 690 | 4.6 |

As shown in Tables 2 to 3, the polishing liquid compositions of Examples 1 to 18 improved the polishing selectivity while maintaining the polishing rate of the silicon oxide film, as compared to the polishing liquid compositions of Comparative Examples 1 and 8, each of which did not contain either the component B or the component C, and the polishing liquid compositions of Comparative Examples 2 to 7 and 9 to 13, each of which did not contain both the component B and the component C.

Further, the polishing rate of the silicon nitride film and the dishing rate during overpolishing were evaluated by using each of the polishing liquid compositions of Examples 19 to 22 and Comparative Example 14. The evaluation method is as follows

[Patterned Substrate]

A commercially available wafer for evaluating CMP characteristics (“P-TEOS MIT 864 PT wafer” manufactured by ADVANTEC, diameter: 300 min) was used as a patterned substrate for evaluation. This patterned substrate had been etched to make a linear pattern of projections and recesses. Each projection was formed of a silicon nitride film (first layer) with a thickness of 150 nm and a silicon oxide film (second layer) with a thickness of 450 ern. Similarly, the silicon oxide film with a thickness of 450 nm was provided in each recess. A difference in level between the projection and the recess was 350 nm. The silicon oxide film was composed of P-TEOS. The projections and the recesses, each having a line width of 100 μm, were used as measuring objects.

[Planarization Time]

The blanket substrates with a diameter of 300 mm (corresponding to the silicon oxide film and the silicon nitride film) and the above patterned substrate were polished with each of the polishing liquid compositions of Examples 19 to 22 and Comparative Examples 14 under the following polishing conditions. The time (sec) required for planarization of the protruding silicon oxide film was measured and defined as a planarization time Table 4 shows the results.

<Polishing Conditions>

Polishing device: single-sided polishing machine (“FREX-300” manufactured by EBARA CORPORATION)

Polishing pad: hard urethane pad (“IC-1000/Suba 400” manufactured by Nitta Haas Inc.)

Surface plate rotation speed: 100 rpm

Head rotation speed: 107 rpm

Polishing load: 300 g weight/cm²

Supply of polishing liquid: 200 mL/min

Polishing time: 1 minute (for each of the silicon oxide film substrate and the silicon nitride film substrate), planarization time+overpolishing time (for the patterned substrate)

[Polishing Rate of Silicon Nitride Film During Overpolishing]

After the silicon nitride film was exposed due to the planarization of the protruding silicon oxide film, the patterned substrate was excessively polished for a period of time that was 20% of the time it took to planarize the protruding silicon oxide film (i.e., the planarization time) The thickness of the silicon nitride film was measured before and after excessive polishing with Spectra FX200 (manufactured by KLA Corporation). The polishing rate of the slam nitride film during overpolishing was calculated by the following formula. Table 4 shows the results.

Polishing rate of silicon nitride film after exposure of nitride film (Å/sec)=[thickness of silicon nitride film at the start of exposure of nitride film (Å)−thickness of silicon nitride film at the end of polishing (Å)]/overpolishing time (sec)

[Dishing Rate During Overpolishing]

After the silicon nitride film was exposed due to the planarization of the protruding silicon oxide film, the patterned substrate was excessively polished for a period of time that was 20% of the time it took to planarize the protruding silicon oxide film (i.e., the planarization time) The thickness of the silicon oxide film disposed in a recess was measured before and after excessive polishing with Spectra FX200 (manufactured by KLA Corporation). The dishing rate during overpolishing was calculated by the following formula. Table 4 shows the results.

Polishing rate of silicon oxide film in recess after exposure of nitride film (Å/sec)=[thickness of silicon oxide film in recess at the start of exposure of nitride film (Å)−thickness of silicon oxide film in recess at the end of polishing (Å)]/overpolishing time (sec)

TABLE 4

| | Polishing liquid composition | | | | | | | |
|---|---|---|---|---|---|---|---|---|
| | Cerium | | | | | | | |
| | oxide | | | | | | | |
| | particle | Water-soluble polymer | | | Anionic condensation product | | | |
| | (component | (component B) | | | (component C) | | | |
| | A) | | Type of | | | Type of | | |
| | Content | | constituent | Content | | constituent | Content | pH |
| Table 4 | (mass %) | Type | monomer | (mass %) | Type | monomer | (mass %) | (25° C.) |
| Ex. 19 | 0.15 | B1 | MPC | 0.01 | C1 | BisS/PhS | 0.006 | 5 |
| Ex. 20 | 0.15 | B2 | MPC/BMA | 0.01 | C1 | BisS/PhS | 0.006 | 5 |
| Ex, 21 | 0.15 | B3 | MPC/SMA | 0.01 | C1 | BisS/PhS | 0.006 | 5 |
| Ex. 22 | 0.15 | B3 | MPC/SMA | 0.015 | C1 | BisS/PhS | 0.006 | 5 |
| Comp. Ex, 14 | 0.15 | B1 | MPC | 0.01 | — | — | — | 5 |

| | Blanket substrate | | | | | |
|---|---|---|---|---|---|---|
| | | | Polishing | Patterned substrate | | |
| | | | selectivity | | Overpolishing | |
| | Polishing rate | | Ratio of | | Polishing | |
| | Silicon | Silicon | polishing rate | Planar- | rate of | |
| | oxide | nitride | (silicon oxide | ization | silicon | Dishing |
| | film | film | film/silicon | time | nitride film | rate |
| Table 4 | Å/min | Å/min | nitride film) | sec | Å/sec | Å/sec |
| Ex. 19 | 2584 | 106 | 24.3 | 210 | 0.7 | 6.5 |
| Ex. 20 | 2450 | 55 | 44.5 | 120 | 0.4 | 5.4 |
| Ex, 21 | 2429 | 42 | 57.8 | 120 | 1.1 | 11 |
| Ex. 22 | 2517 | 51 | 49.4 | 120 | 1.4 | 1.3 |
| Comp. Ex, 14 | 4336 | 540 | 8.0 | 90 | 12.9 | 23.3 |

As shown in Table 4, the polishing liquid compositions of Examples 19 to 22 improved the polishing selectivity while maintaining the polishing rate of the silicon oxide film, as compared to the polishing liquid composition of Comparative Example 14, which did not contain the component C. Moreover, the polishing liquid compositions of Examples 19 to 22 were found to reduce the polishing rate of the silicon nitride film and the dishing rate during overpolishing as compared to the polishing liquid composition of Comparative Example 14.

7. Evaluation of Polishing Liquid Composition (Examples 23 to 35, Comparative Examples 15 to 20)

[Production of Test Piece]

A silicon oxide film (blanket file) with a thickness of 2000 nm was formed on one side of a silicon wafer by a TEOS-plasma CVD method. A square piece of 40 mm×40 mm was cut from the silicon water having the silicon oxide film, providing a silicon oxide film test piece (blanket substrate).

Similarly, a silicon nitride film (blanket film) with a thickness of 70 nm was formed on one side of a silicon wafer by a CND method. A square piece of 40 mm×40 mm was cut from the silicon wafer having the silicon nitride film, providing a silicon nitride film test piece (blanket substrate).

[Polishing Rate of Silicon Oxide Film (Film to be Polished)]

A polishing device was “TriboLab CMP” manufactured by Bruker. A polishing pad was a hard urethane pad “IC-1000/Suba 400” manufactured by Nitta Haas Inc. The polishing pad was attached to the surface plate of the polishing device. The silicon oxide film test piece was set in a holder; and the holder was placed on the polishing pad with the surface of the test piece, on which the silicon oxide film had been formed, facing down (i.e., with the silicon oxide film facing the polishing pad). Moreover, a weight was put on the holder so that the load applied to the test piece was 300 g weight/cm². The silicon oxide film test piece was polished by rotating the surface plate and the holder in the same direction respectively at 100 rpm/min and 107 rpm/min while the polishing liquid composition was dropped at a rate of 50 mL/min on the center of the surface plate to which the polishing pad was attached. Then, the polished test piece was cleaned with ultrapure water and dried. The resulting silicon oxide film test piece was used as a measuring object for an optical interference film thickness measuring device, as will be described below.

The thickness of the silicon oxide film was measured before and after polishing with the optical interference film thickness measuring device (“VM-1230” manufactured by SCREEN Semiconductor Solutions Co., Ltd). The polishing rate of the silicon oxide film was calculated by the following formula. Table 5 shows the results.

Polishing rate of silicon oxide film (Å/min)=[thickness of silicon oxide film before polishing (Å)−thickness of silicon oxide film after polishing (Å)]/polishing time (min)

[Polishing Rate of Silicon Nitride Film (Polishing Stopper Film)]

The silicon nitride film was polished and the thickness of the silicon nitride film was measured in the same manner as the measurement of the polishing rate of the silicon oxide film, as described above, except that the silicon nitride film test piece was used instead of the silicon oxide film test piece. The polishing rate of the silicon nitride film was calculated by the following formula. Table 5 Shows the results.

Polishing rate of silicon nitride film (Å/min)=[thickness of silicon nitride film before polishing (Å)−thickness of silicon nitride film after polishing (Å)]/polishing time (min)

[Polishing Selectivity (Ratio of Polishing Rate)]

The ratio of the polishing rate of the silicon oxide film to the polishing rate of the silicon nitride film was calculated by the following formula as a ratio of polishing rate. Table 5 shows the results. The higher the polishing selectivity, the larger the ratio of polishing rate.

Ratio of polishing rate=polishing rate of silicon oxide film (Å/min)/polishing rate of silicon nitride film (Å/min)

TABLE 5

| | Polishing liquid composition | | | | | | | | |
|---|---|---|---|---|---|---|---|---|---|
| | Cerium | | | | | | | | |
| | oxide | | | | | | | | |
| | particle | Water-soluble polymer | | | Anionic compound (component C) | | | | |
| | (component | (component B) | | | | | Molar | | |
| | A) | | Type of | | | Type of | ratio of | | |
| | Content | | constituent | Content | | constituent | constituent | Molecular | Content |
| Table 5 | (mass %) | Type | monomer | (mass %) | Type | monomer | monomer | weight | (mass %) |
| Ex. 23 | 0.15 | B2 | MPC/BMA | 0.01 | C1 | BisS/PhS | 2.5/97.5 | 1300 | 0.06 |
| Ex. 24 | 0.15 | B2 | MPC/BMA | 0.01 | C1 | BisS/PhS | 2.5/97.5 | 1300 | 0.06 |
| Ex. 25 | 0.15 | B2 | MPC/BMA | 0.01 | C1 | BisS/PhS | 2.5/97.5 | 1300 | 0.06 |
| Ex. 26 | 0.15 | B2 | MPC/BMA | 0.01 | C1 | BisS/PhS | 2.5/97.5 | 1300 | 0.06 |
| Ex. 27 | 0.15 | B2 | MPC/BMA | 0.01 | C1 | BisS/PhS | 2.5/97.5 | 1300 | 0.06 |
| Ex. 28 | 0.15 | B2 | MPC/BMA | 0.01 | C1 | BisS/PhS | 2.5/97.5 | 1300 | 0.06 |
| Ex. 29 | 0.15 | B2 | MPC/BMA | 0.01 | C9 | BisS/PhS | 50/50 | 1300 | 0.06 |
| Ex. 30 | 0.15 | B2 | MPC/BMA | 0.01 | C6 | naphthalenesulfonic acid | | 3000 | 0.04 |
| Ex. 31 | 0.15 | B2 | MPC/BMA | 0.01 | C1 | BisS/PhS | 2.5/97.5 | 1300 | 0.06 |
| Ex. 32 | 0.15 | B2 | MPC/BMA | 0.01 | C1 | BisS/PhS | 2.5/97.5 | 1300 | 0.06 |
| Ex. 33 | 0.15 | B5 | MPC/VP | 0.01 | C1 | BisS/PhS | 2.5/97.5 | 1300 | 0.06 |
| Ex. 34 | 0.15 | B6 | MPC/aMSt | 0.01 | C1 | BisS/PhS | 2.5/97.5 | 1300 | 0.06 |
| Ex. 35 | 0.15 | B1 | MPC | 0.01 | C1 | BisS/PhS | 2.5/97.5 | 1300 | 0.06 |
| Comp. Ex. 15 | 0.15 | B2 | MPC/BMA | 0.01 | — | — | — | — | — |
| Comp, Ex. 16 | 0.15 | — | — | — | C1 | BisS/PhS | 2.5/97.5 | 1300 | 0.06 |
| Comp. Ex. 17 | 0.15 | — | — | — | — | — | — | — | — |
| Comp. Ex. 18 | 0.15 | — | — | — | C1 | BisS/PhS | 2.5/97.5 | 1300 | 0.06 |
| Comp. Ex. 19 | 0.15 | B2 | MPC/BMA | 0.01 | — | — | | — | — |
| Comp. Ex. 20 | 0.15 | B2 | MPC/BMA | 0.01 | C10 | AA/AMPS | | | 0.06 |
| | | Polishing liquid composition | | | | | | | Polishing |
| | | Compound having | | | | | | | selectivity |
| | | group represented | | | | | Polishing rate | | Ratio of |
| | | by —[(CHX)ₚ—O]_{q}— | | | | | Silicon | Silicon | polishing rate |
| | | (component D) | | | | | oxide | nitride | (silicon oxide |
| | | | | Moleclular | Content | pH | film | film | film/silicon |
| | Table 5 | Type | | weight | (mass %) | (25° C.) | Å/min | Å/min | nitride film) |
| | Ex. 23 | — | — | — | — | 5 | 3809.8 | 40.4 | 94.3 |
| | Ex. 24 | D1 | PEG | 20000 | 0.05 | 5 | 5067.4 | 19.2 | 263.9 |
| | Ex. 25 | D1 | PEG | 20000 | 0.10 | 5 | 4981.8 | 11.2 | 444.8 |
| | Ex. 26 | D1 | PEG | 20000 | 0.30 | 5 | 4742 | 10.8 | 439.1 |
| | Ex. 27 | D1 | PEG | 20000 | 0.50 | 5 | 4850.6 | 7.2 | 673.7 |
| | Ex. 28 | D5 | 50-mer of | 4600 | 0.10 | 5 | 2899 | 19.2 | 151.0 |
| | | | polyglycerol | | | | | | |
| | Ex. 29 | D1 | PEG | 20000 | 0.30 | 5 | 4281.6 | 29 | 147.6 |
| | Ex. 30 | D1 | PEG | 20000 | 0.30 | 5 | 2942.8 | 19.2 | 153.3 |
| | Ex. 31 | D1 | PEG | 20000 | 0.30 | 5 | 3319.6 | 19.4 | 171.1 |
| | Ex. 32 | D1 | PEG | 20000 | 0.30 | 5 | 2828.4 | 15.0 | 188.6 |
| | Ex. 33 | D1 | PEG | 20000 | 0.30 | 5 | 2944.6 | 10.4 | 283.1 |
| | Ex. 34 | D1 | PEG | 20000 | 0.30 | 5 | 3519.8 | 27.6 | 127.5 |
| | Ex. 35 | D1 | PEG | 20000 | 0.30 | 5 | 4503.2 | 12 | 375.3 |
| | Comp. Ex. 15 | — | — | — | — | 5 | 6187.8 | 480.4 | 12.9 |
| | Comp, Ex. 16 | — | — | — | — | 5 | 1303.8 | 16.4 | 79.5 |
| | Comp. Ex. 17 | D1 | PEG | 20000 | 0.10 | 5 | 5114 | 383.2 | 13.3 |
| | Comp. Ex. 18 | D1 | PEG | 20000 | 0.10 | 5 | 813.6 | 10.6 | 76.8 |
| | Comp. Ex. 19 | D1 | PEG | 20000 | 0.10 | 5 | 4862.8 | 500.8 | 9.7 |
| | Comp. Ex. 20 | D1 | PEG | 20000 | 0.10 | 5 | 1413.4 | 51.2 | 27.6 |

As shown in Table 5, the polishing liquid compositions of Examples 24 to 35, each of which further contained the component D, further improved the polishing selectivity while maintaining the polishing rate of the silicon oxide film, as compared to the polishing liquid composition of Example 23, which did not contain the component D. Moreover, the polishing liquid compositions of Examples 24 to 35 improved the polishing selectivity while maintaining the polishing rate of the silicon oxide film, as compared to the polishing liquid compositions of Comparative Examples 15 to 20, each of which did not contain at least one of the components B to D.

6. Evaluation of Polishing Liquid Composition (Examples 36 to 51, Comparative Examples 21 to 26)

[Production of Test Piece]

A silicon oxide film with a thickness of 2000 nm was formed on one side of a silicon wafer by a TECHS-plasma CVD method. A square piece of 40 mm×40 mm was cut from the silicon wafer having the silicon oxide film, providing a silicon oxide film test piece. Similarly, first, a thermal oxidation film with a thickness of 100 nm was formed on one side of a silicon wafer, and then a polysilicon film With a thickness of 500 nm was formed by a CVD method. A square piece of 40 mm×40 mm was cut from the silicon water having the thermal oxidation film and the polysilicon film, providing a polysilicon film test piece.

[Measurement of Polishing Rate of Silicon Oxide Film]

The polishing rate of the silicon oxide film was calculated by using each of the polishing liquid compositions of Examples 36 to 51 and Comparative Examples 21 to 26 in the same manner as the measurement of the polishing rate of the silicon oxide film which used the polishing liquid compositions of Examples 23 to 35 and Comparative Examples 15 to 20, as described above. Table 6 shows the polishing rate of the silicon oxide film.

[Measurement of Polishing Rate of Polysilicon Film]

The polysilicon film was polished, the thickness of the polysilicon film was measured, and the polishing rate of the polysilicon film was calculated in the same manner as the measurement of the polishing rate of the silicon oxide film, as described above, except that the polysilicon film test pied was used instead of the silicon oxide film test piece. Table 6 shows the polishing rate of the polysilicon film.

[Polishing Selectivity (Ratio of Polishing Rate)]

The ratio of the polishing rate of the silicon (Aide film to the polishing rate of the polysilicon film (SiO₂/Poly-Si) was calculated by the following formula as a ratio of polishing rate. The better the polishing selectivity, the lager the ratio of polishing rate. Such polishing liquid compositions have a high ability to eliminate steps. Table 6 shows the results.

Ratio of polishing rate=polishing rate of silicon oxide film (Å/min)/polishing rate of poly-silicon film (Å/min)

TABLE 6

| | Polishing liquid composition | | | | | | | | |
|---|---|---|---|---|---|---|---|---|---|
| | Cerium | | | | | | | | |
| | oxide | | | | | | | | |
| | particle | Water-soluble polymer | | | Anionic compound (component C) | | | | |
| | (component | (component B) | | | | | Molar | | |
| | A) | | Type of | | | Type of | ratio of | | |
| | Content | | constituent | Content | | constituent | constituent | Molecular | Content |
| Table 6 | (mass %) | Type | monomer | (mass %) | Type | monomer | monomer | weight | (mass %) |
| Ex. 36 | 0.15 | B2 | MPC/BMA | 0.01 | C1 | BisS/PhS | 2.5/97.5 | 1300 | 0.06 |
| Ex. 37 | 0.15 | B2 | MPC/BMA | 0.01 | C1 | BisS/PhS | 2.5/97.5 | 1300 | 0.06 |
| Ex. 38 | 0.15 | B2 | MPC/BMA | 0.01 | C1 | BisS/PhS | 2.5/97.5 | 1300 | 0.06 |
| Ex. 39 | 0.15 | B2 | MPC/BMA | 0.01 | C1 | BisS/PhS | 2.5/97.5 | 1300 | 0.06 |
| Ex. 40 | 0.15 | B2 | MPC/BMA | 0.01 | C1 | BisS/PhS | 2.5/97.5 | 1300 | 0.06 |
| Ex. 41 | 0.15 | B2 | MPC/BMA | 0.01 | C1 | BisS/PhS | 2.5/97.5 | 1300 | 0.06 |
| Ex. 42 | 0.15 | B2 | MPC/BMA | 0.01 | C1 | BisS/PhS | 2.5/97.5 | 1300 | 0.06 |
| Ex. 43 | 0.15 | B2 | MPC/BMA | 0.01 | C1 | BisS/PhS | 2.5/97.5 | 3000 | 0.06 |
| Ex. 44 | 0.15 | B2 | MPC/BMA | 0.01 | C1 | BisS/PhS | 2.5/97.5 | 1300 | 0.06 |
| Ex. 45 | 0.15 | B2 | MPC/BMA | 0.01 | C9 | BisS/PhS | 50/50 | 1300 | 0.06 |
| Ex. 46 | 0.15 | B2 | MPC/BMA | 0.01 | C6 | naphthalenesulfonic acid | | 3000 | 0.04 |
| Ex. 47 | 0.15 | B2 | MPC/BMA | 0.01 | C1 | BisS/PhS | 2.5/97.5 | 1300 | 0.06 |
| Ex. 48 | 0.15 | B2 | MPC/BMA | 0.01 | C1 | BisS/PhS | 2.5/97.5 | 1300 | 0.06 |
| Ex. 49 | 0.15 | B5 | MPC/VP | 0.01 | C1 | BisS/PhS | 2.5/97.5 | 1300 | 0.06 |
| Ex. 50 | 0.15 | B6 | MPC/aMSt | 0.01 | C1 | BisS/PhS | 2.5/97.5 | 1300 | 0.06 |
| Ex. 51 | 0.15 | B1 | MPC | 0.01 | C1 | BisS/PhS | 2.5/97.5 | 1300 | 0.06 |
| Comp. Ex. 21 | 0.15 | — | MPC/BMA | 0.01 | — | — | — | — | — |
| Comp, Ex. 22 | 0.15 | — | — | — | C1 | BisS/PhS | 2.5/97.5 | 1300 | 0.06 |
| Comp. Ex. 23 | 0.15 | — | — | — | — | — | — | — | — |
| Comp. Ex. 24 | 0.15 | — | — | — | C1 | BisS/PhS | 2.5/97.5 | 1300 | 0.06 |
| Comp. Ex. 25 | 0.15 | B2 | MPC/BMA | 0.01 | — | — | — | — | — |
| Comp. Ex. 26 | 0.15 | B2 | MPC/BMA | 0.01 | C10 | AA/AMPS | | | 0.06 |
| | | Polishing liquid composition | | | | | | | Polishing |
| | | Compound having | | | | | | | selectivity |
| | | group represented | | | | | Polishing rate | | Ratio of |
| | | by —[(CHX)ₚ—O]_{q}— | | | | | Silicon | Poly- | polishing rate |
| | | (component D) | | | | | oxide | silicon | (silicon oxide |
| | | | | Moleclular | Content | pH | film | film | film/poly- |
| | Table 6 | Type | | weight | (mass %) | (25° C.) | Å/min | Å/min | silicon film) |
| | Ex. 36 | — | — | — | — | 5 | 3809.8 | 501.6 | 7.6 |
| | Ex. 37 | D1 | PEG | 20000 | 0.01 | 5 | 5067.4 | 36 | 140.8 |
| | Ex. 38 | D1 | PEG | 20000 | 0.025 | 5 | 4981.8 | 31.2 | 159.7 |
| | Ex. 39 | D1 | PEG | 20000 | 0.05 | 5 | 4742 | 22.4 | 211.7 |
| | Ex. 40 | D1 | PEG | 20000 | 0.10 | 5 | 4850.6 | 35 | 138.6 |
| | Ex. 41 | D2 | PEG | 1540 | 0.05 | 5 | 5680 | 75.4 | 75.3 |
| | Ex. 42 | D3 | PEG | 4000 | 0.05 | 5 | 5801.4 | 58 | 100.0 |
| | Ex. 43 | D4 | PEG | 8000 | 0.05 | 5 | 5466.4 | 41.8 | 130.8 |
| | Ex. 44 | D5 | 50-mer of | 4600 | 0.10 | 5 | 2899 | 63.4 | 45.7 |
| | | | polyglycerol | | | | | | |
| | Ex. 45 | D1 | PEG | 20000 | 0.05 | 5 | 4281.6 | 26.8 | 159.8 |
| | Ex. 46 | D1 | PEG | 20000 | 0.05 | 5 | 2942.8 | 65 | 45.3 |
| | Ex. 47 | D1 | PEG | 20000 | 0.05 | 6 | 3319.6 | 31 | 107.1 |
| | Ex. 48 | D1 | PEG | 20000 | 0.05 | 7 | 2828.4 | 35.4 | 79.9 |
| | Ex. 49 | D1 | PEG | 20000 | 0.05 | 5 | 2944.6 | 34.8 | 84.6 |
| | Ex. 50 | D1 | PEG | 20000 | 0.05 | 5 | 3519.8 | 47.2 | 74.6 |
| | Ex. 51 | D1 | PEG | 20000 | 0.05 | 5 | 4386.4 | 40.8 | 107.5 |
| | Comp. Ex. 21 | — | — | — | — | 5 | 6187.8 | 1619.2 | 3.8 |
| | Comp, Ex. 22 | — | — | — | — | 5 | 1303.8 | 458.6 | 2.8 |
| | Comp. Ex. 23 | D1 | PEG | 20000 | 0.10 | 5 | 5114 | 337.6 | 15.1 |
| | Comp. Ex. 24 | D1 | PEG | 20000 | 0.10 | 5 | 813.6 | 74.6 | 10.9 |
| | Comp. Ex. 25 | D1 | PEG | 20000 | 0.10 | 5 | 4862.8 | 340.2 | 14.3 |
| | Comp. Ex. 26 | D1 | PEG | 20000 | 0.10 | 5 | 1413.4 | 55 | 25.7 |

As shown in Table 6, the polishing liquid compositions of Examples 37 to 51, each of which further contained the component D, further improved the polishing selectivity while maintaining the polishing rate of the silicon oxide film, as compared to the polishing liquid composition of Example 36, which did not contain the component D. Moreover, the polishing liquid compositions of Examples 37 to 51 improved the polishing selectivity while maintaining the polishing rate of the silicon oxide film, as compared to the polishing liquid compositions of Comparative Examples 21 to 26, each of which did not contain at least one of the components B to D.

### INDUSTRIAL APPLICABILITY

The polishing liquid composition of the present disclosure is useful in a method for producing a semiconductor substrate for high density or high integration.

1. A polishing liquid composition for a silicon oxide film, comprising:
cerium oxide particles (component A);
a water-soluble polymer (component B);
an anionic condensate (component C); and
an aqueous medium,
wherein the component B is a polymer containing a constitutional unit b1 represented by the following formula (I): 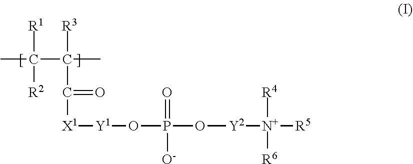
where R¹, R², R³, R⁴, R⁵, and R⁶ are the same or different and represent a hydrogen atom, a methyl group, or an ethyl group, X¹ represents O or NH, and Y¹ and Y² are the same or different and represent an alkylene group having 1 to 4 carbon atoms.

2. The polishing liquid composition according to claim 1, wherein the component B is a copolymer containing the constitutional unit b1 represented by the formula (I) and at least one constitutional unit b2 selected from the group consisting of a constitutional unit represented by the following formula (II), a constitutional unit represented by the following formula (III), and a constitutional unit represented by the following formula (IV): 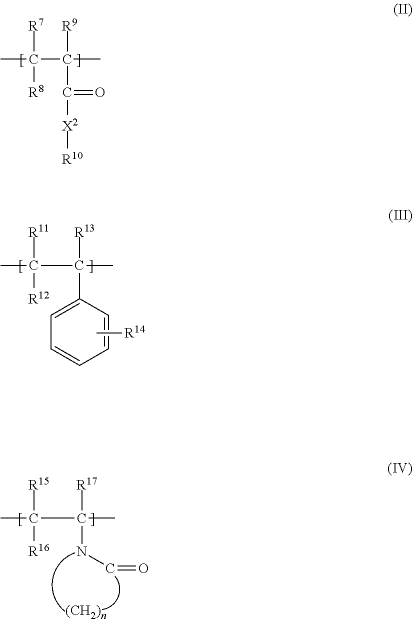
where R⁷, R⁸, and R⁹ are the same or different and represent a hydrogen atom, a methyl group, or an ethyl group, X² represents O or NH, and R¹⁰ represents a hydrocarbon group,
where R¹¹, R¹², and R¹³ are the same or different and represent a hydrogen atom, a methyl group, or an ethyl group and R¹⁴ represents a hydrogen atom, a hydroxyl group, a hydrocarbon group, or an alkoxy group,
where R¹⁵, R¹⁶, and R¹⁷ are the same or different and represent a hydrogen atom, a methyl group, or an ethyl group and n represents an integer of 2 to 12.

3. The polishing liquid composition according to claim 1, wherein the component B is a homopolymer composed of the constitutional unit b1 represented by the formula (I).

4. The polishing liquid composition according to claim 1, wherein the constitutional unit b1 represented by the formula (I) is a constitutional unit derived from a monomer containing a methacryloyloxyethyl phosphobetaine structure.

5. The polishing liquid composition according to claim 1, wherein the component C is a formaldehyde condensate having an anionic group.

6. The polishing liquid composition according to claim 1, wherein the component C is an anionic condensate having an aromatic ring in a main chain.

7. The polishing liquid composition according to claim 1, wherein the component C is a condensate containing a constitutional unit with a structure derived from an aromatic monomer having an anionic group.

8. The polishing liquid composition according to claim 7, wherein the constitutional unit with a structure derived from an aromatic monomer having an anionic group has a structure in which at least one hydrogen atom of the aromatic ring in the main chain is substituted with a sulfonic acid group.

9. The polishing liquid composition according to claim 7, wherein the component C further contains at least one selected from the group consisting of a constitutional unit c1 represented by the following formula (V) and a constitutional unit c2 represented by the following formula (VI): 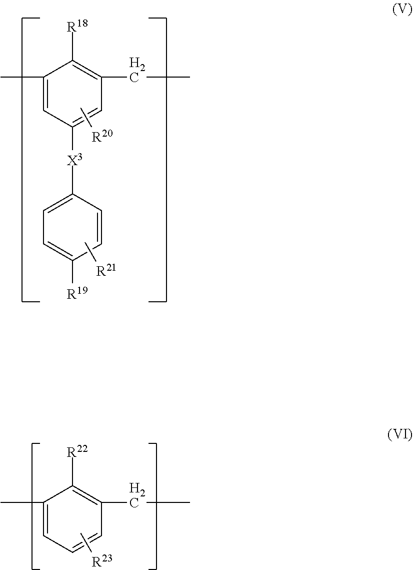
where R¹⁸ and R¹⁹ are the same or different and represent a hydrogen atom or —OM¹, M¹ represents at least one selected from the group consisting of alkali metal, alkaline earth metal, organic cation, ammonium, and a hydrogen atom, R²⁰ and R²¹ are the same or different and represent a hydrogen atom, an alkyl group, an alkoxy group, an aralkyl group, or —OM², M² represents at least one selected from the group consisting of alkali metal, alkaline earth metal, organic cation, ammonium, and a hydrogen atom, and X³ represents a bond, —CH₂—, —S—, —SO₂—, —C(CH₃)₂—, or 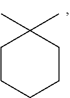
where R²² represents a hydrogen atom or —OM³, M³ represents at least one selected from the group consisting of alkali metal, alkaline earth metal, organic cation, ammonium, and a hydrogen atom, R²³ represents a hydrogen atom, an alkyl group, an alkoxy group, an aralkyl group, or —OM⁴, and M⁴ represents at least one selected from the group consisting of alkali metal, alkaline earth metal, organic cation, ammonium, and a hydrogen atom.

10. The polishing liquid composition according to claim 1, wherein a content of the component C is 0.001% by mass or more and 1% by mass or less.

11. The polishing liquid composition according to claim 1, wherein a mass ratio B/C of the component B to the component C is 0.1 or more and 20 or less.

12. The polishing liquid composition according to claim 1, wherein a molecular weight of the component C is 6,000 or less.

13. The polishing liquid composition according to claim 1, wherein a content of the component A is 0.001% by mass or more and 10% by mass or less.

14. The polishing liquid composition according to claim 1, further comprising a compound (component D) having a group represented by the following formula (VII):
—[(CHX)ₚ—O]_{q}— (VII)
where X represents a hydrogen atom or OH, p represents a number of 2 or more and 5 or less, and q represents a number of 5 or more and 10,000 or less, in which if p is 2 or more, X's are the same or different.

15. The polishing liquid composition according to claim 14, wherein the component D is polyethylene glycol or polyglycerol.

16. A method for producing a semiconductor substrate, comprising:
polishing a film to be polished with the polishing liquid composition according to claim 1.

17. A polishing method comprising:
polishing a film to be polished with the polishing liquid composition according to claim 1.
